(19) United States
(12) Patent Application Publication
(10) Pub. No.: US 2012/0146242 A1
(43) Pub. Date: Jun. 14, 2012

(54) SEMICONDUCTOR DEVICE AND METHOD OF FABRICATING THE SAME

(75) Inventors: Hiroyuki Fujishima, Tokyo (JP); Dai Sasaki, Tokyo (JP); Satoshi Isa, Tokyo (JP); Mitsuaki Katagiri, Tokyo (JP)

(73) Assignee: Elpida Memory, Inc.

(21) Appl. No.: 13/323,246

(22) Filed: Dec. 12, 2011

(30) Foreign Application Priority Data
Dec. 13, 2010 (JP) 2010-277256
Mar. 18, 2011 (JP) 2011-061140

(51) Int. Cl. H01L 23/498

(52) U.S. Cl. 257/777; 257/E23.06

(57) ABSTRACT

A semiconductor device includes a wiring board, a stack of semiconductor chips, and a first sealing member. The wiring board has a first surface. The wiring board includes a first insulating layer formed over the first surface. The first insulating layer has a first opening. The stack of semiconductor chips is mounted over the first surface of the wiring board. The stack of semiconductor chips includes a first semiconductor chip. The first semiconductor chip is closer to the wiring board than the other semiconductor chips. The first sealing member seals at least the first semiconductor chip. The first sealing member includes a protruding portion. The first opening of the insulating layer faces toward the protruding portion of the first sealing member.

### BACKGROUND OF THE INVENTION

1. Field of the Invention

The present invention relates to a semiconductor device and a method of fabricating the same.

Priorities are claimed on Japanese Patent Applications Nos. 2010-277256, filed Dec. 13, 2010 and 2011-061140, filed Mar. 18, 2011, the contents of which are incorporated herein by reference.

2. Description of the Related Art

In recent years, high integration of semiconductor devices has improved every year and thus large scale chip size or miniaturization and multi-layer of wirings has progressed. There is a need for reduction and thinning of a package size to mount packages with high density.

According to the demand, techniques referred to as a multi-chip package (MCP) in which a plurality of semiconductor chips are mounted on one wiring board with high density have been developed. Among these techniques, chip on chip (CoC) type semiconductor packages (semiconductor devices) in which a chip stack body, in which semiconductor chips having through electrodes referred to as through silicon vias (TSVs) are stacked, is mounted on one surface of the wiring board have been attracting attention.

A method of fabricating a CoC type semiconductor package includes encapsulating a chip stack body by sequentially stacking a plurality of semiconductor chips constituting the chip stack body on a wiring board, filling each gap of the loaded semiconductor chips with an underfill material (a first encapsulant), and thermally hardening the underfill material. Further, the method includes encapsulating one surface of the wiring board with a mold resin (a second encapsulant) to cover the entire chip stack body including the underfill material. These are disclosed in Japanese Patent Application Laid-Open No. 2006-319243 and Japanese Patent Application Laid-Open No. 2007-36184.

In the semiconductor chips constituting the chip stack body, a bump electrode provided in one surface of each semiconductor chip and a bump electrode provided in the other surface of each semiconductor chip are thermo-compression-bonded (bump-bonded) with the one surface and the other surface of each semiconductor chip facing each other.

Since the chip stack body is constituted by stacking a plurality of semiconductor chips, the chip stack body can easily become thick. To promote the thinning of the chip stack body, it is necessary to thin the semiconductor chip to a thickness of about 50 μm. However, if the semiconductor chip is thinned, when the underfill material is thermally hardened, internal stress due to hardening shrinkage or thermal expansion of the underfill material is applied to the chip stack body in which the semiconductor chips are stacked.

In this case, since deformation of the semiconductor chip such as warpage occurs and stress is applied to a bonding portion of the above-described bump electrode (bump bonding portion), the bump bonding portion is broken or a crack in the semiconductor chip is caused.

Since a shape of a fillet formed in the surroundings when supplying the underfill material is unstable, a width of the fillet is increased due to spread of the underfill material and thus a size of a package is increased.

Technology that suppresses occurrence of fracture in bonding portions of semiconductor chips constituting a chip stack body or occurrence of cracks in the semiconductor chips by filling an underfill material in each gap of the semiconductor chips and then mounting the chip stack body on a wiring board has been proposed. These are disclosed in Japanese Patent Application Laid-Open No. 2010-251347.

In the above-described CoC type semiconductor package, when filling each gap of semiconductor chips constituting a chip stack body with an underfill material, the underfill material which sticks out from the surroundings of the chip stack body protrudes to an upper surface of a semiconductor chip positioned in an uppermost layer. Thereby, when the chip stack body is mounted on a wiring board, the protruding portion of the underfill material interferes with the wiring board. In this case, a bump electrode of the semiconductor chip positioned in the uppermost layer of the chip stack body is not connected with a pad electrode of the side of the wiring board well and thus reliability of the semiconductor package is degraded.

### SUMMARY

In one embodiment, a semiconductor device, may include, but is not limited to, a wiring board, a stack of semiconductor chips, and a first sealing member. The wiring board has a first surface. The wiring board includes a first insulating layer formed over the first surface. The first insulating layer has a first opening. The stack of semiconductor chips is mounted over the first surface of the wiring board. The stack of semiconductor chips includes a first semiconductor chip. The first semiconductor chip is closer to the wiring board than the other semiconductor chips. The first sealing member seals at least the first semiconductor chip. The first sealing member includes a protruding portion. The first opening of the insulating layer faces toward the protruding portion of the first sealing member.

In another embodiment, a semiconductor device may include, but is not limited to, a first semiconductor chip, a second semiconductor chip, a first sealing member, and a wiring board. The first semiconductor chip has a first surface. The first semiconductor chip includes a first electrode formed on the first surface thereof. The second semiconductor chip is stacked over the first surface of the first semiconductor chip. The second semiconductor chip includes a second electrode formed on a second surface thereof and a third electrode formed on a third surface thereof. The second surface faces the first surface of the first semiconductor chip so as to electrically couple the first electrode to the second electrode. The first sealing member seals at least the second semiconductor chip without covering the third electrode. The first sealing member includes a protruding portion that protrudes from the third surface of the second semiconductor chip. The wiring board is stacked over the third surface of the second semiconductor chip and includes an insulating layer formed on a fourth surface thereof. The insulating layer includes an opening. The fourth surface faces the third surface of the second semiconductor chip so that the protruding portion of the first sealing member arranges in the opening of the insulating layer.

In still another embodiment, a semiconductor device may include, but is not limited to, a first semiconductor chip including a first electrode formed on a first surface thereof; a second semiconductor chip smaller than the first semiconductor chip staking over the first surface of the first semiconductor chip and including a second electrode formed on a second surface thereof and a third electrode formed on a third surface thereof, the second surface facing toward the first surface of the first semiconductor chip so as to electrically couple the first electrode to the second electrode; a first sealing member that seals at least the first semiconductor chip without covering the third electrode, and the first sealing member including a protruding portion that protrudes over the third surface of the second semiconductor chip; and a wiring board stacking over the third surface of the second semiconductor chip and including a connection pad formed on a fourth surface thereof and an insulating layer formed on the fourth surface, the insulating layer including an opening to expose the connection pad from the insulating layer, the fourth surface facing the third surface of the second semiconductor chip so as to electrically couple the third electrode to the connection pad, wherein the opening of the insulating layer is larger in size than the second semiconductor chip, and is smaller in size than the first semiconductor chip, the second semiconductor chip is positioned in the opening in plan view, and the protruding portion of the first sealing member being disposed in the opening.

In yet another embodiment, a semiconductor device may include, but is not limited to, a first semiconductor chip, a second semiconductor chip, and a first sealing member. The first semiconductor chip includes a first electrode formed on a first surface thereof. The second semiconductor chip is stacked over the first surface of the first semiconductor chip. The second semiconductor chip includes a second electrode formed on a second surface thereof and a third electrode formed on a third surface thereof. The second surface faces the first surface of the first semiconductor chip so as to electrically couple the first electrode to the second electrode. The first sealing member seals at least the second semiconductor chip without covering the third electrode. The first sealing member includes a protruding portion that protrudes from the third surface of the second semiconductor chip.

In a furthermore embodiment, a wiring board may include, but is not limited to, an insulating body, an insulating body, a plurality of connection pads, and an insulating layer. The insulating body includes a first surface and a second surface opposed to the first surface. The plurality of connection pads is formed on the first surface of the insulating body. The insulating layer is formed over the first surface of the insulating body. The insulating layer includes a first opening to expose the plurality of connection pads from the insulating layer and a second opening differing from the first opening.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a cross sectional elevation view of a semiconductor package in accordance with a first embodiment of the present invention;

FIG. 1B is a cross sectional elevation view of a semiconductor package in accordance with a modified embodiment to the first embodiment of the present invention;

FIG. 2A is a fragmentary cross sectional elevation view of a semiconductor device in a step involved in a method of forming the semiconductor package of FIG. 1A;

FIG. 2B is a fragmentary cross sectional elevation view of a semiconductor device in a step, subsequent to the step of FIG. 2A, involved in the method of forming the semiconductor package of FIG. 1A;

FIG. 2C is a fragmentary cross sectional elevation view of a semiconductor device in a step, subsequent to the step of FIG. 2B, involved in the method of forming the semiconductor package of FIG. 1A;

FIG. 3A is a fragmentary cross sectional elevation view of a semiconductor device in a step, subsequent to the step of FIG. 2C, involved in the method of forming the semiconductor package of FIG. 1A;

FIG. 3B is a fragmentary cross sectional elevation view of a semiconductor device in a step, subsequent to the step of FIG. 3A, involved in the method of forming the semiconductor package of FIG. 1A;

FIG. 3C is a fragmentary cross sectional elevation view of a semiconductor device in a step, subsequent to the step of FIG. 3B, involved in the method of forming the semiconductor package of FIG. 1A;

FIG. 4A is a perspective view of a stack of semiconductor chips sealed with a first sealing material in accordance with the first embodiment of the present invention;

FIG. 4B is a cross sectional elevation view of the stack of semiconductor chips sealed with the first sealing material of FIG. 4A;

FIG. 5A is a plan view of a mother board to be used to form the semiconductor package of FIG. 1A;

FIG. 5B is a fragmentary cross sectional elevation view of the mother board of FIG. 5A;

FIG. 6A is a fragmentary cross sectional elevation view of a step involved in a method of mounting the stack of semiconductor chips of FIGS. 4A and 4B onto the mother board of FIGS. 5A and 5B;

FIG. 6B is a fragmentary cross sectional elevation view of a step, subsequent to the step of FIG. 6A, involved in the method of mounting the stack of semiconductor chips of FIGS. 4A and 4B onto the mother board of FIGS. 5A and 5B;

FIG. 6C is a fragmentary cross sectional elevation view of a step, subsequent to the step of FIG. 6B, involved in the method of mounting the stack of semiconductor chips of FIGS. 4A and 4B onto the mother board of FIGS. 5A and 5B;

FIG. 6D is a fragmentary cross sectional elevation view of a step, subsequent to the step of FIG. 6C, involved in the method of mounting the stack of semiconductor chips of FIGS. 4A and 4B onto the mother board of FIGS. 5A and 5B;

FIG. 7 is a fragmentary cross sectional elevation view of a step, subsequent to the step of FIG. 6D, involved in a method of sealing the semiconductor package of FIG. 1A;

FIG. 8 is a fragmentary cross sectional elevation view of a step, subsequent to the step of FIG. 7, involved in the method of sealing the semiconductor package of FIG. 1A;

FIG. 9 is a fragmentary cross sectional elevation view of a step, subsequent to the step of FIG. 8, involved in a method of cutting the mother board to form the semiconductor package of FIG. 1A;

FIG. 10A is a plan view of an IF chip in a modified embodiment of the present invention;

FIG. 10B is a cross sectional elevation view of the IF chip of FIG. 10A;

FIG. 11A is a fragmentary cross sectional elevation view of the stack of semiconductor chips in a step involved in a process of filling an under-filling material into gaps between the semiconductor chips;

FIG. 11B is a fragmentary cross sectional elevation view of the stack of semiconductor chips in a step, subsequent to the step of FIG. 11A, involved in the process of filling the under-filling material into the gaps between the semiconductor chips;

FIG. 11C is a fragmentary cross sectional elevation view of the stack of semiconductor chips in a step, subsequent to the step of FIG. 11B, involved in the process of filling the under-filling material into the gaps between the semiconductor chips;

FIG. 11D is a fragmentary cross sectional elevation view of the stack of semiconductor chips in a step, subsequent to the step of FIG. 11C, involved in the process of filling the under-filling material into the gaps between the semiconductor chips;

FIG. 12A is a plan view of another IF chip in a further modified embodiment of the present invention;

FIG. 12B is a cross sectional elevation view of the other IF chip of FIG. 12A;

FIG. 13 is a cross sectional elevation view of another semiconductor package in another embodiment of the present invention;

FIG. 14A is a plan view of one surface of a wiring board for the semiconductor package of FIG. 13;

FIG. 14B is a plan view of another surface of a wiring board for the semiconductor package of FIG. 13;

FIG. 15A is a fragmentary cross sectional elevation view of a step involved in a method of stacking semiconductor chips to form the semiconductor package of FIG. 13;

FIG. 15B is a fragmentary cross sectional elevation view of a step, subsequent to the step of FIG. 15A, involved in a method of stacking semiconductor chips to form the semiconductor package of FIG. 13;

FIG. 15C is a fragmentary cross sectional elevation view of a step, subsequent to the step of FIG. 15B, involved in a method of stacking semiconductor chips to form the semiconductor package of FIG. 13;

FIG. 16A is a fragmentary cross sectional elevation view of a step, subsequent to the step of FIG. 15C, involved in a method of filling the under-filling material into the gaps between the semiconductor chips to form the semiconductor package of FIG. 13;

FIG. 16B is a fragmentary cross sectional elevation view of a step, subsequent to the step of FIG. 16A, involved in a method of filling the under-filling material into the gaps between the semiconductor chips to form the semiconductor package of FIG. 13;

FIG. 16C is a fragmentary cross sectional elevation view of a step, subsequent to the step of FIG. 16B, involved in a method of filling the under-filling material into the gaps between the semiconductor chips to form the semiconductor package of FIG. 13;

FIG. 17A is a perspective view of a stack of semiconductor chips sealed with a first sealing material in accordance with the other embodiment of the present invention;

FIG. 17B is a cross sectional elevation view of the stack of semiconductor chips sealed with the first sealing material of FIG. 13;

FIG. 18A is a plan view of a mother board;

FIG. 18B is a fragmentary cross sectional elevation view of the mother board of FIG. 18A;

FIG. 19A is a fragmentary cross sectional elevation view of a step involved in a method of mounting a stack of semiconductor chips on the mother board to form the semiconductor package of FIG. 13;

FIG. 19B is a fragmentary cross sectional elevation view of a step, subsequent to the step of FIG. 19A, involved in the method of mounting the stack of semiconductor chips on the mother board to form the semiconductor package of FIG. 13;

FIG. 19C is a fragmentary cross sectional elevation view of a step, subsequent to the step of FIG. 19B, involved in the method of mounting the stack of semiconductor chips on the mother board to form the semiconductor package of FIG. 13;

FIG. 19D is a fragmentary cross sectional elevation view of a step, subsequent to the step of FIG. 19C, involved in the method of mounting the stack of semiconductor chips on the mother board to form the semiconductor package of FIG. 13;

FIG. 20 is a fragmentary cross sectional elevation view of a step, subsequent to the step of FIG. 19D, involved in a method of sealing the stack of semiconductor chips with a mold resin to form the semiconductor package of FIG. 13;

FIG. 21 is a fragmentary cross sectional elevation view of a step, subsequent to the step of FIG. 20, involved in a method of placing solder balls on the mother board to form the semiconductor package of FIG. 13; and

FIG. 22 is a fragmentary cross sectional elevation view of a step, subsequent to the step of FIG. 21, involved in a method of cutting the mother board to form the semiconductor package of FIG. 13.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device, may include, but is not limited to, a wiring board, a stack of semiconductor chips, and a first sealing member. The wiring board has a first surface. The wiring board includes a first insulating layer formed over the first surface. The first insulating layer has a first opening. The stack of semiconductor chips is mounted over the first surface of the wiring board. The stack of semiconductor chips includes a first semiconductor chip. The first semiconductor chip is closer to the wiring board than the other semiconductor chips. The first sealing member seals at least the first semiconductor chip. The first sealing member includes a protruding portion. The first opening of the insulating layer faces toward the protruding portion of the first sealing member.

In some cases, the protruding portion is disposed in the first opening of the insulating layer.

In some cases, the protruding portion covers a first side of the first semiconductor chip.

In some cases, the semiconductor device may further include, but is not limited to, a protecting film which covers a first surface of the first semiconductor chip. The first surface of the first semiconductor chip faces toward the first surface of the wiring board. The protecting film has a second opening. The second opening extends along the first side of the first semiconductor chip. The second opening receives the protruding portion.

In some cases, the semiconductor device may further include, but is not limited to, a second sealing member formed over the first surface of the wiring board to cover the stack of semiconductor chips and the first sealing material.

In some cases, each of the semiconductor chips includes a via electrode. The semiconductor chips is electrically coupled with each other through the via electrode.

In some cases, the first semiconductor chip is smaller in size than the other semiconductor chips. The protruding portion of the first sealing member is positioned inside the other semiconductor chips in plan view.

In some cases, the semiconductor device may further include a third sealing member that seals the other semiconductor chips except for the first semiconductor chip. The first sealing member seals the first semiconductor chip.

In some cases, the wiring board includes a connection pad formed on the first surface thereof. The connection pad is positioned in the first opening of the first insulating layer. The connection pad is electrically coupled to the via electrode of the semiconductor chips.

In some cases, the wiring board includes a via electrode which penetrates the wiring board. The via is positioned outside the first opening of the first insulating layer.

In some cases, the semiconductor device may further include, but is not limited to, an external terminal formed over a second surface that is opposed to the first surface of the wiring board. The external terminal is positioned outside the first opening of the first insulating layer in plan view. The external terminal is electrically coupled to the connection pad through the via electrode.

In another embodiment, a semiconductor device may include, but is not limited to, a first semiconductor chip, a second semiconductor chip, a first sealing member, and a wiring board. The first semiconductor chip has a first surface. The first semiconductor chip includes a first electrode formed on the first surface thereof. The second semiconductor chip is stacked over the first surface of the first semiconductor chip. The second semiconductor chip includes a second electrode formed on a second surface thereof and a third electrode formed on a third surface thereof. The second surface faces the first surface of the first semiconductor chip so as to electrically couple the first electrode to the second electrode. The first sealing member seals at least the second semiconductor chip without covering the third electrode. The first sealing member includes a protruding portion that protrudes from the third surface of the second semiconductor chip. The wiring board is stacked over the third surface of the second semiconductor chip and includes an insulating layer formed on a fourth surface thereof. The insulating layer includes an opening. The fourth surface faces the third surface of the second semiconductor chip so that the protruding portion of the first sealing member arranges in the opening of the insulating layer.

In some cases, the second semiconductor chip is smaller in size than the first semiconductor chip.

In some cases, the semiconductor device may further include, but is not limited to, a third semiconductor chip provided between the first and second semiconductor chip and including a fourth electrode formed on a fifth surface thereof and a fifth electrode formed on a sixth surface thereof. The fourth surface faces the first surface of the first semiconductor chip so as to electrically coupling the first electrode to the fourth electrode. The fifth surface faces the second surface of the second semiconductor chip so as to electrically couple the second electrode to the fifth electrode.

In some cases, the wiring board includes a connection pad formed on the fourth surface thereof. The connection pad is positioned in the opening of the insulating layer. The connection pad is electrically coupled to the third electrode of the second semiconductor chip.

In some cases, the semiconductor device may further include, but is not limited to, an external terminal provided over the seventh surface that is opposed to the fourth surface of the wiring board. The external terminal is electrically coupled to the connection pad through a via electrode.

In some cases, the external terminal and the via electrode are positioned outside the opening in plan view.

In some cases, the third surface of the second semiconductor chip includes an uneven portion adjacent to a first side, the protruding portion of the first sealing member being disposed over the first side of the second semiconductor chip.

In still another embodiment, a semiconductor device may include, but is not limited to, a first semiconductor chip including a first electrode formed on a first surface thereof; a second semiconductor chip smaller than the first semiconductor chip staking over the first surface of the first semiconductor chip and including a second electrode formed on a second surface thereof and a third electrode formed on a third surface thereof, the second surface facing toward the first surface of the first semiconductor chip so as to electrically couple the first electrode to the second electrode; a first sealing member that seals at least the first semiconductor chip without covering the third electrode, and the first sealing member including a protruding portion that protrudes over the third surface of the second semiconductor chip; and a wiring board stacking over the third surface of the second semiconductor chip and including a connection pad formed on a fourth surface thereof and an insulating layer formed on the fourth surface, the insulating layer including an opening to expose the connection pad from the insulating layer, the fourth surface facing the third surface of the second semiconductor chip so as to electrically couple the third electrode to the connection pad, wherein the opening of the insulating layer is larger in size than the second semiconductor chip, and is smaller in size than the first semiconductor chip, the second semiconductor chip is positioned in the opening in plan view, and the protruding portion of the first sealing member being disposed in the opening.

In some cases, the semiconductor device may further include an external terminal provided over the fifth surface that is opposed to the fourth surface of the wiring board, the external terminal being electrically couple to the connection pad through a via electrode. The external terminal and the via are positioned outside the opening in plan view.

In yet another embodiment, a semiconductor device may include, but is not limited to, a first semiconductor chip, a second semiconductor chip, and a first sealing member. The first semiconductor chip includes a first electrode formed on a first surface thereof. The second semiconductor chip is stacked over the first surface of the first semiconductor chip. The second semiconductor chip includes a second electrode formed on a second surface thereof and a third electrode formed on a third surface thereof. The second surface faces the first surface of the first semiconductor chip so as to electrically couple the first electrode to the second electrode. The first sealing member seals at least the second semiconductor chip without covering the third electrode. The first sealing member includes a protruding portion that protrudes from the third surface of the second semiconductor chip.

In a furthermore embodiment, a wiring board may include, but is not limited to, an insulating body, an insulating body, a plurality of connection pads, and an insulating layer. The insulating body includes a first surface and a second surface opposed to the first surface. The plurality of connection pads is formed on the first surface of the insulating body. The insulating layer is formed over the first surface of the insulating body. The insulating layer includes a first opening to expose the plurality of connection pads from the insulating layer and a second opening differing from the first opening.

Hereinafter, a semiconductor device to which the present invention is applied and a method of fabricating the same will be described with reference to the drawings in detail.

In the drawings used in the following description, for clarity, the feature portions may be exaggerated to understand the features easily, but it is not limited that a dimension ratio, and the like of each component are equal to that of the substantial semiconductor device. Further, a material, a dimension, and the like illustrated in the following description may be an example. The present invention may not be necessarily limited thereto and may be appropriately modified and implemented without departing from the spirit and scope of the present invention

### (Semiconductor Device)

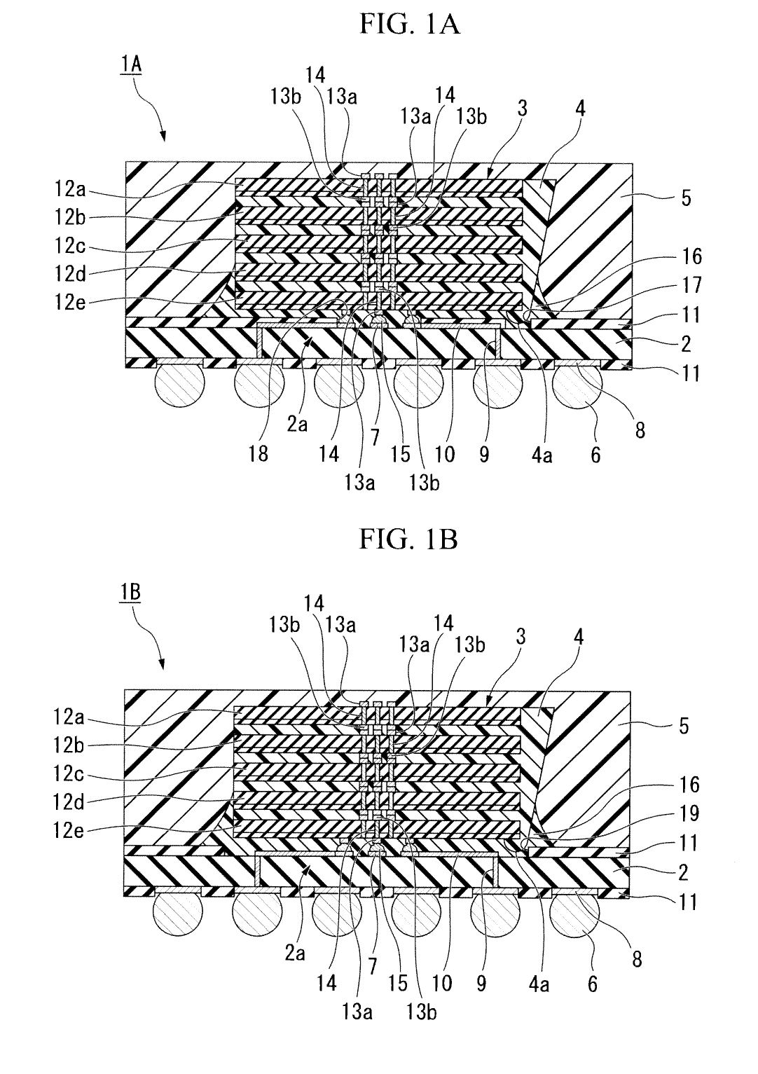

First, as an example of a semiconductor device to which the present invention is applied, a CoC type semiconductor package 1A illustrated in FIG. 1A will be described.

As shown in FIG. 1A, the semiconductor package 1A has a package structure referred to as a ball grid array (BGA) including a wiring board 2, a chip stack body 3 mounted on one surface (an upper surface) of the wiring board 2, a first encapsulant 4 encapsulating the chip stack body 3, a second encapsulant 5 encapsulating the one surface of the wiring board 2 with the first encapsulant 4 covered, and a plurality of solder balls (external connection terminals) disposed in the other surface (bottom surface) of the wiring board 2

The wiring board 2 includes a rectangular print wiring board when viewed in a planar view. For example, the print wiring board includes a board in which a conductor pattern formed of a conductive material such as copper (Cu) of which a surface is gold (Au)-plated, and the like is formed on a surface of an insulating base material formed of a glass epoxy resin, and the like and a surface thereof is coated with an insulating film such as a solder resist. In this example, the wiring board 2 having a thickness of about 0.2 mm is used.

A mounting area 2a on which the chip stack body 3 is to be mounted is provided in a central portion of the upper surface of the wiring board 2. A plurality of pad electrodes (third connection terminals) 7 are arranged in parallel in the mounting area 2a of the wiring board 2. On the other hand, a plurality of connection lands 8 are arranged in parallel in the other surface (a bottom surface) of the wiring board 2. The solder balls 6 are disposed on the connection lands 8. In addition, a via (an inter-layer connection portion) 9, a wiring pattern 10, or the like for electrically connecting the pad electrode 7 and the connection land 8 are disposed in the wiring board 2. An insulating film 11 covers a surface of the wiring board 2 other than a portion in which the above-described pad electrode 7 or the above-described connection land 8 is formed.

The chip stack body 3 includes a plurality (5 in this example) of stacked semiconductor chips 12a to 12e and has a structure that a plurality (4 in this example) of memory chips (first semiconductor chips) 12a to 12d in which a dynamic random access memory (DRAM) circuit, and the like is formed, and an interface (IF) chip (a second semiconductor chip) 12e in which an IF circuit for interfacing between each memory chip 12a to 12e and the wiring board 2, and the like is formed, are stacked from an upper layer side in order. In this example, the semiconductor chips 12a to 12e having a thickness of about 50 μm are used.

Among the semiconductor chips, the plurality of memory chips 12a to 12d are rectangular when viewed in a planar view, and have a shape smaller than the wiring board 2. Each memory chip 12a to 12d includes a plurality of first bump electrodes (first connection terminals) 13a in one surface thereof, a plurality of second bump electrodes (second connection terminals) 13b in the other surface thereof, and a plurality of through electrodes (TSVs) 14 connecting the first bump electrodes 13a and the second bump electrodes 13b. While facing each one surface and each other surface of the plurality of memory chips 12a to 12d, the first bump electrodes 13a and the second bump electrodes 13b therebetween are bonded so that the plurality of memory chips 12a to 12d are stacked.

Meanwhile, the IF chip 12e is rectangular when viewed in a planar view, and has a size approximately equal to that of the memory chips 12a to 12d. The IF chip 12e includes a plurality of first bump electrodes (first connection terminals) 13a in one surface thereof, a plurality of second bump electrodes (second connection terminals) 13b in the other surface thereof, and a plurality of through electrodes (TSVs) 14 connecting the first bump electrodes 13a and the second bump electrodes 13b. While the one surface of the IF chip 12e and the other surface of the memory chip 12d face each other, the first bump electrodes 13a and the second bump electrodes 13b therebetween are bonded so that the IF chip 12e is stacked

When the IF chip 12e of the chip stack body 3 positioned in an uppermost layer faces downward, while the other surface of the IF chip 12e and the one surface (the mounting area 2a) of the wiring board 2 face each other, the second bump electrodes 13b and the pad electrodes 7 therebetween are bonded via wire bumps (bonding members) 15. Further, the chip stack body 3 is adhered and fixed to the mounting area 2a of the wiring board 2 via an insulative adhesion member 16 filled within a gap between the one surface of the wiring board 2 and the other surface of the IF chip 12e.

Further, the second bump electrodes 13b of the IF chip 12e are aligned with the pad electrode 7 of the wiring board 2 so that the second bump electrodes 13b of the IF chip 12e have an interval (200 μm or more) larger than those of the second bump electrodes 13b of the memory chips 12a to 12d. Thus, in the IF chip 12e, a wiring pattern (not shown) for redistribution is provided between the second bump electrode 13b and the through electrode 14 so that the interval of the second bump electrodes 13b may be adjusted with respect to the interval of the pad electrodes 7 of the wiring board 2.

The first encapsulant 4 encapsulates the chip stack body 3 with an underfill material filled within each gap of the plurality of memory chips 12a to 12d and the IF chip 12e constituting the chip stack body 3.

The second encapsulant 5 completely encapsulates one surface side of the wiring board 2 with a mold resin covering the entire chip stack body 3 encapsulated with the first encapsulant 4.

However, when the underfill material is filled within each gap of the semiconductor chips 12a to 12e constituting the chip stack body 3, the underfill material sticking out from the surroundings of the chip stack body 3 protrudes to an upper surface of the IF chip 12e positioned in an uppermost layer and thus the protruding portion 4a elevated upward from the upper surface of the IF chip 12e is formed in the first encapsulant 4. The protruding portion 4a is elevated, for example, about 30 μm from the upper surface of the IF chip 12e and disposed along one side of the chip stack body 3.

With respect to this, the semiconductor package 1A to which the present invention is applied is configured such that an opening 17 escaping the protruding portion 4a of the first encapsulant 4 sticking out from the surroundings of the chip stack body 3 is provided in the insulating film 11 of the wiring board 2 so that the protruding portion 4a of the first encapsulant 4 does not interfere with the wiring board 2 when the chip stack body 3 is mounted on the wiring board 2. The opening 17 is formed by removing a portion of the insulating film 11 covering the surface of the wiring board 2 in accordance with a position and a shape of the protruding portion 4a of the first encapsulant 4. In this example, the opening 17 is formed to a size of about 600 μm with clearance of about 400 μm in an inner side and about 200 μm in an outer side from a position corresponding to one side of the chip stack body 3.

Therefore, in the semiconductor package 1A to which the present invention is applied, while avoiding interference of the protruding portion 4a of the first encapsulant 4 with the wiring board 2, between the other surface of the IF chip 12e and the one surface (the mounting area 2a) of the wiring board 2, it is possible to appropriately bond the second bump electrode 13b and the pad electrode 7 therebetween via the wire bump (a connection member) 15. Therefore, according to the present invention, it is possible to promote the thinning of the chip stack body 3 and obtain the semiconductor package 1A with high connection reliability between the chip stack body 3 and the wiring board 2.

### (Method of Fabricating Semiconductor Device)

Next, as a method of fabricating a semiconductor device to which the present invention is applied, a process of fabricating the semiconductor package 1A illustrated in FIG. 1A will be described.

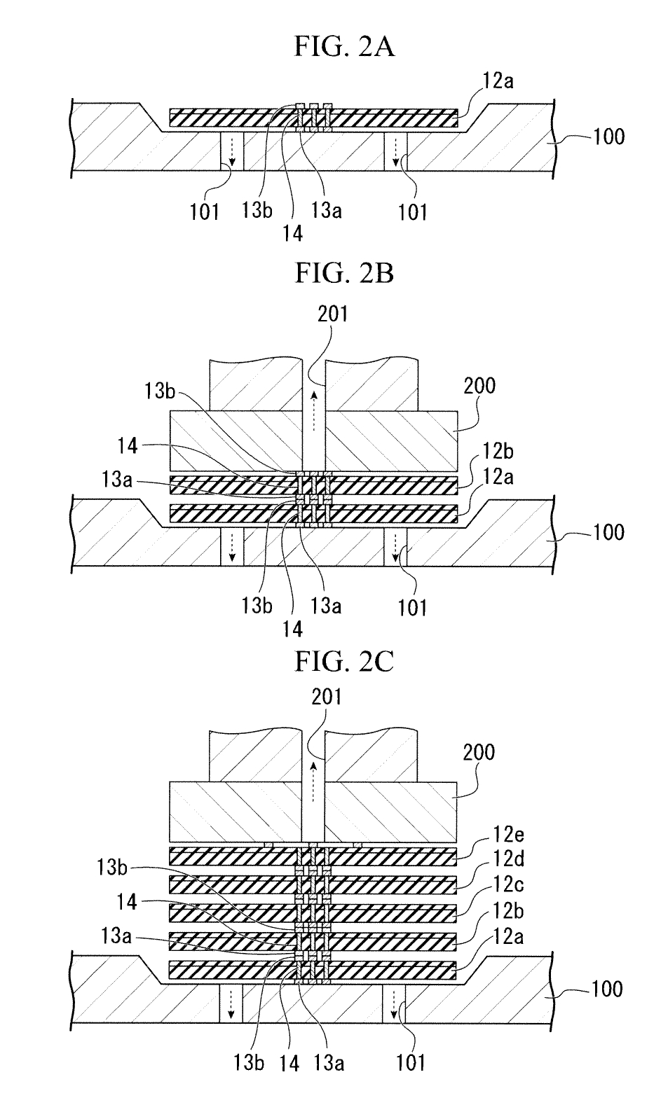

When the semiconductor package 1A is fabricated, first, as shown in FIGS. 2A to 2C, while facing each one surface and each other surface of the plurality of semiconductor chips 12a to 12e, a first bump electrode 13a and a second bump electrode 13b therebetween are bonded so that the semiconductor chips 12a to 12e are stacked.

Specifically, as shown in FIG. 2A, a memory chip 12a of a first layer is placed on a suction stage 100 with a surface (one surface) on which a plurality of first bump electrodes 13a are formed facing downward. The memory chip 12a is suctioned by a plurality of suction holes 101 provided in the suction stage 100 so that the memory chip 12a is held on the suction stage 100.

From this state, as shown in FIG. 2B, a memory chip 12b of a second layer is stacked and mounted (flip-chip mounted) on the memory chip 12a of the first layer using a bonding tool 200. In flip-chip mounting, while the memory chip 12b of the second layer is suctioned and held by suction holes 201 provided in the bonding tool 200, the bonding tool 200 holds the memory chip 12b of the second layer such that a surface (one surface) in which the first bump electrode 13a is formed faces downward.

While facing the one surface of the memory chip 12b of the second layer and the other surface of the memory chip 12a of the first layer which is directly below the memory chip 12b of the second layer, the bonding tool 200 places the memory chip 12b of the second layer on the memory chip 12a of the first layer such that positions of the first bump electrodes 13a and the second bump electrodes 13b therebetween are aligned with each other. In this state, while the bonding tool 200 heats at a high temperature (for example, about 300° C.) and applies weight, the first bump electrodes 13a and the second bump electrodes 13b are bonded (flip-chip bonded) by thermocompression. In bonding, ultrasonic waves as well as weight may be applied.

Thereby, the first bump electrodes 13a and the second bump electrodes 13b are electrically connected (flip-chip connected), and the memory chip 12b of the second layer is flip-chip mounted on the memory chip 12a of the first layer.

In this state, further, as shown in FIG. 2C, using the same method as in the above-described case of flip-chip mounting the memory chip 12b of the second layer on the memory chip 12a of the first layer, a memory chip 12c of a third layer on the memory chip 12b of the second layer, a memory chip 12d of a fourth layer on the memory chip 12c of the third layer, and an IF chip 12e of a fifth layer on the memory chip 12d of the fourth layer are flip-chip mounted in order.

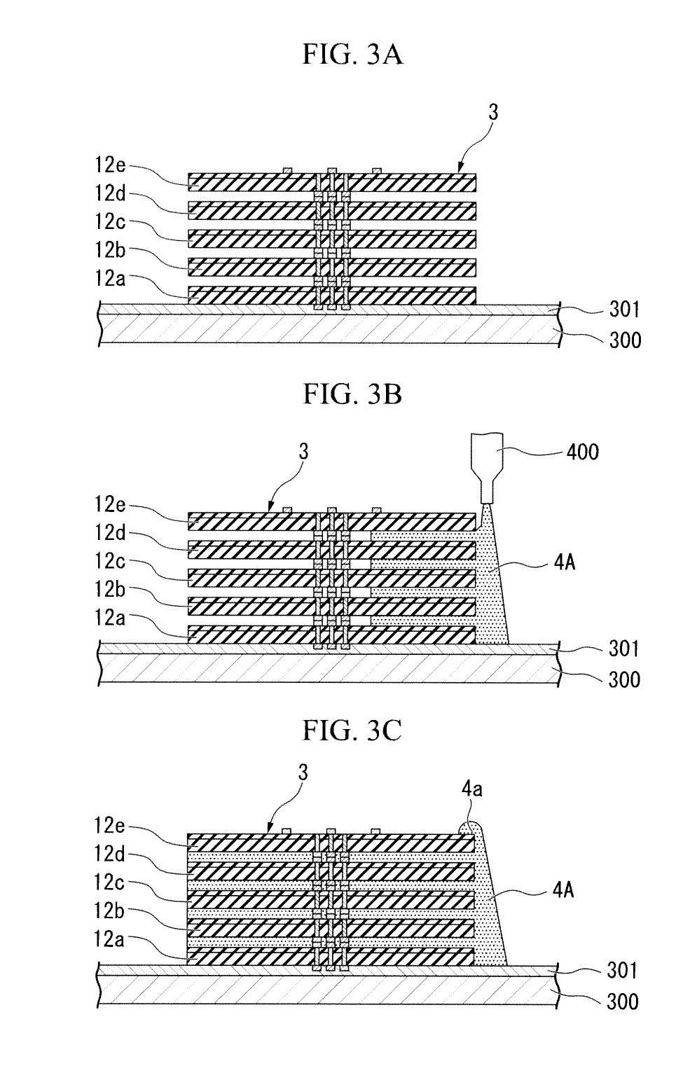

Next, as shown in FIGS. 3A to 3C, an underfill material 4A which is to be the above-described first encapsulant 4 is filled within each gap of the chip stack body 3 in which the plurality of semiconductor chips 12a to 12e are stacked so that the chip stack body 3 is encapsulated.

Specifically, as shown in FIG. 3A, the chip stack body 3 is placed on a coating stage 300. For example, a coating sheet 301 formed of a material having a poor wettability to the underfill material 4A, such as a fluorine-based sheet or a sheet to which a silicon-based adhesive is attached, is stuck on a surface of the coating stage 300.

From this state, as shown in FIG. 3B, using a dispenser 400 supplying the liquid underfill material 4A, the underfill material 4A is coated from the vicinity of an end portion of a position along one side of the chip stack body 3 toward each gap of the chip stack body 3. At this time, the underfill material 4A penetrates and is filled within each gap of the chip stack body 3 by a capillary action.

In the position along one side of the chip stack body 3, as shown in FIG. 3C, the underfill material 4A sticking out from the surroundings of each gap of the chip stack body 3 protrudes to an upper surface of the IF chip 12e positioned in an uppermost layer so that a protruding portion 4a elevated from the surface of the IF chip 12e is formed. Further, since the underfill material 4A sticking out from the surroundings of each gap of the chip stack body 3 is suppressed to spread in a surface by the coating sheet 301 having a poor wettability to the above-described underfill material 4A, even if the underfill material 4A gradually spreads from an upper layer side to a lower layer side in a width direction, it is possible to shrink the width.

From this state, the underfill material 4A is heated (cured), for example, at a temperature of about 150° C. so that the underfill material 4A is hardened. Thereby, the chip stack body 3 encapsulated by the first encapsulant 4 is formed.

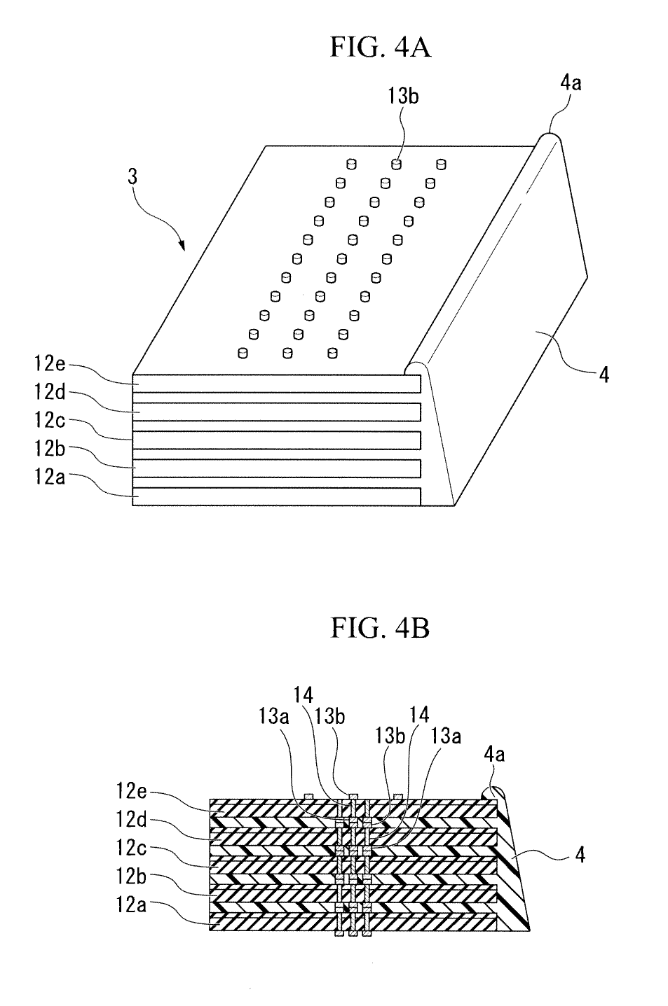

As shown in FIGS. 4A and 4B, the chip stack body 3 encapsulated by the first encapsulant 4 is peeled off from the coating sheet 301. At this time, it is possible to peel off the chip stack body 3 encapsulated by the first encapsulant 4 from the coating sheet 301 having a poor wettability to the underfill material 4A easily. The chip stack body 3 encapsulated by the first encapsulant 4 is contained in a tray for storage (not shown) and transferred to a subsequent process.

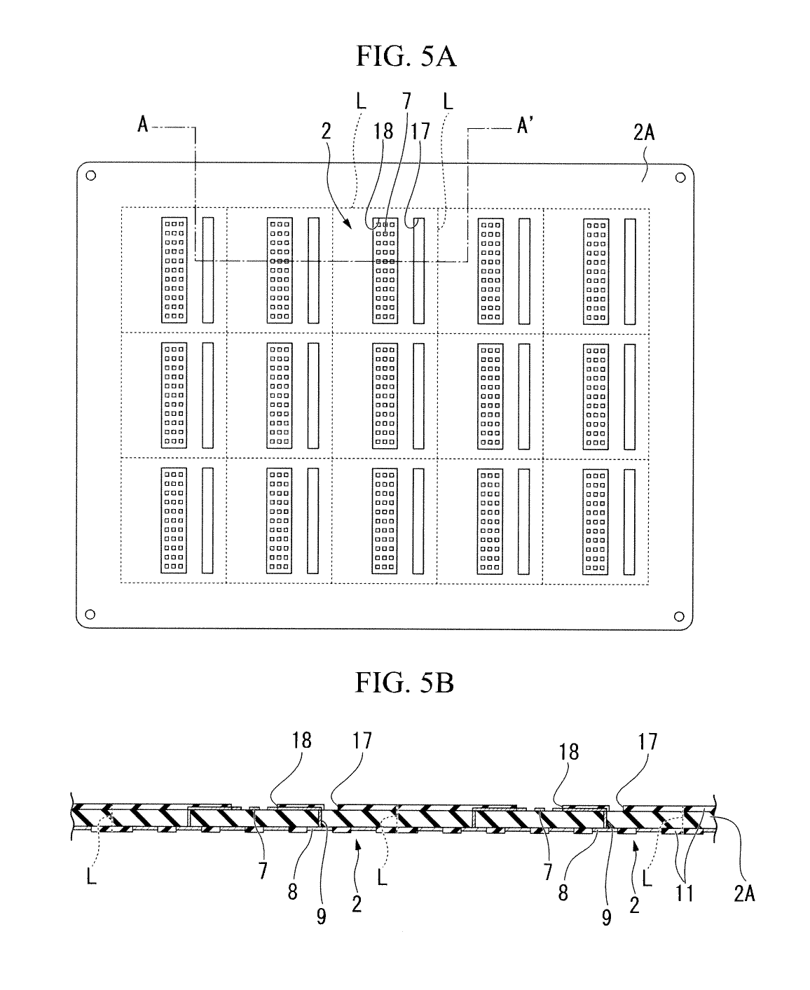

As shown in FIGS. 5A to 5B, a mother wiring board 2A in which a plurality of portions, which are to be the wiring boards 2, are formed in parallel is prepared. For example, the mother wiring board 2A includes a glass epoxy board and the plurality of portions which are to be the wiring boards 2 are formed in parallel in a matrix form and cut finally along a dicing line L so that the portions which are to be the wiring boards 2 can be cut into individual wiring boards 2. Furthermore, in an insulating film 11 covering one surface of the mother wiring board 2A, an opening 17 which escapes the protruding portion 4a of the first encapsulant 4 sticking out from the surroundings of the chip stack body 3, and an opening 18 exposing an area in which the pad electrodes 7 are formed are provided in each portion which is to be the wiring board 2.

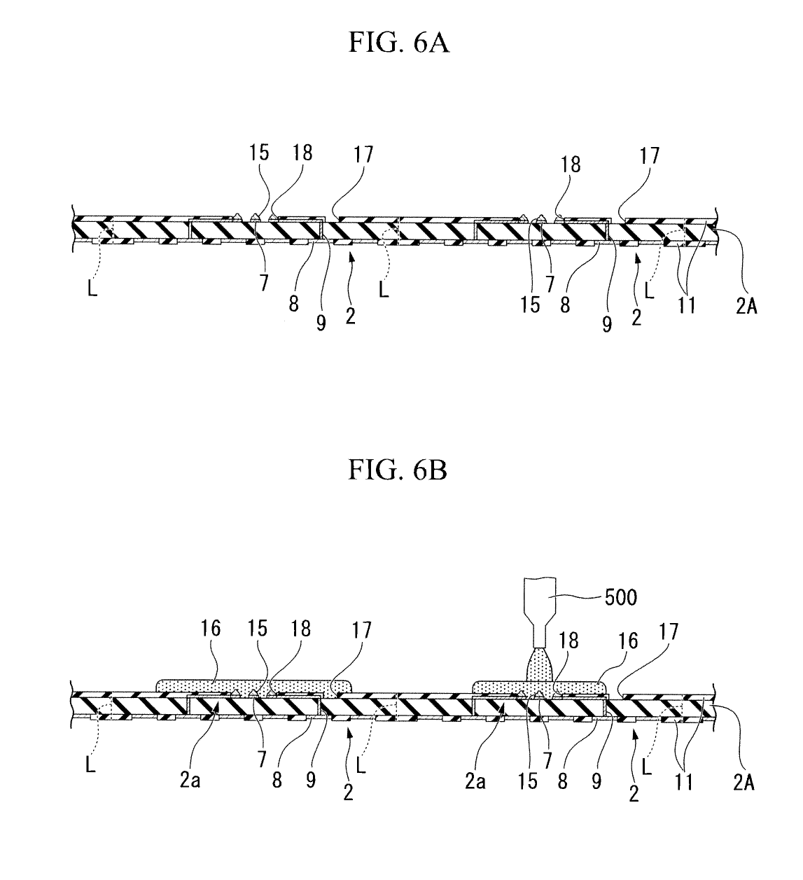

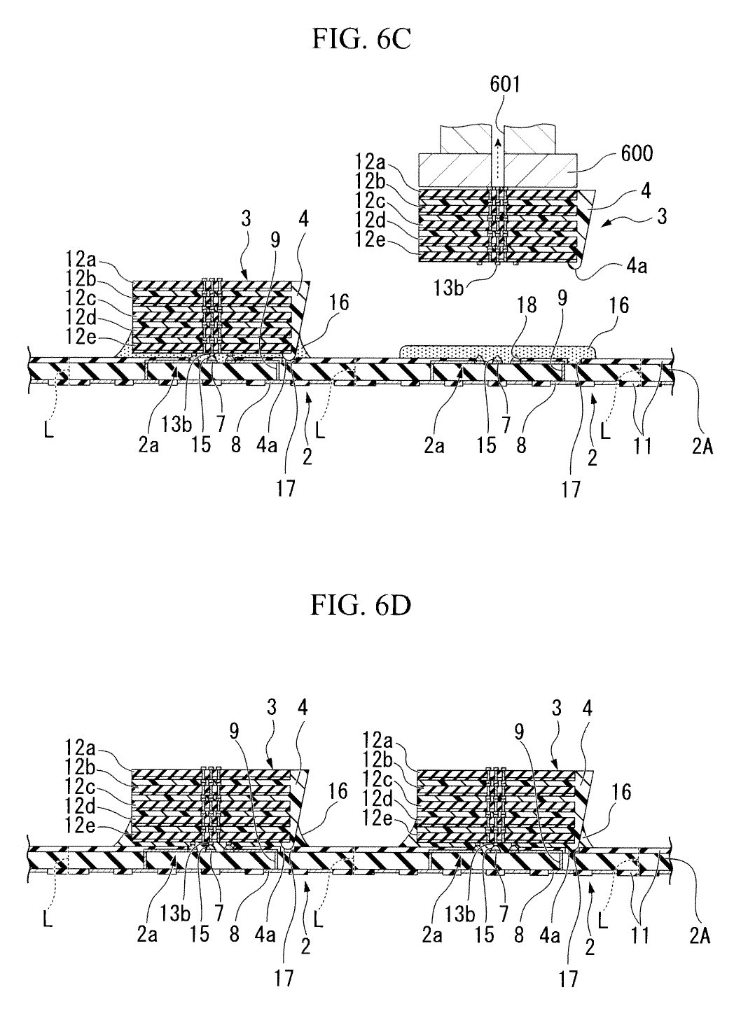

As shown in FIGS. 6A to 6D, in one surface of the mother wiring board 2A, the chip stack body 3 encapsulated by the first encapsulant 4 is mounted in each portion which is to be the wiring board 2.

Specifically, as shown in FIG. 6A, a wire bump 15 is disposed on each pad electrode 7 of the portion which is to be the wiring board 2. For example, the wire bump 15 is formed by forming a melted ball in a front end of a wire formed of gold (Au), copper (Cu), or the like, bonding the ball on the pad electrode 7 by ultrasonic thermocompression using a wire bonding apparatus (not shown), and then pulling and cutting a rear end of the wire.

From this state, as shown in FIG. 6B, using a dispenser 500 supplying a liquid adhesive member 16 referred to as a non-conductive paste (NCP), the adhesive member 16 is coated in each mounting area 2a of the portions which are to be the wiring board 2 on the mother wiring board 2A.

From this state, as shown in FIG. 6C, the chip stack body 3 is flip-chip mounted in the mounting area 2a of the portion which is to be the wiring board 2 of the mother wiring board 2A using a bonding tool 600.

In flip-chip mounting, while the chip stack body 3 is suctioned and held by a suction hole 601 of the bonding tool 600, the bonding tool 600 holds the chip stack body 3 with the IF chip 12e facing downward.

While the IF chip 12e faces the mounting area 2a of the portion which is to be the wiring board 2, the bonding tool 600 places the chip stack body 3 encapsulated by the first encapsulant 4 on the mounting area 2a of the portion which is to be the wiring board 2 such that positions of the second bump electrode 13b and the pad electrode 7 therebetween are aligned with each other. In this state, the bonding tool 600 heats at a high temperature (for example, 300° C.) and applies weight so that the second bump electrode 13b and the pad electrode 7 are bonded (flip-chip bonded) via the wire bump 15 by thermo-compression. In bonding, ultrasonic waves as well as weight may be applied.

Thereby, as shown in FIG. 6D, the second bump electrode 13b and the pad electrode 7 are electrically bonded (flip-chip bonded) via the wire bump 15 so that the chip stack body 3 encapsulated by the first encapsulant 4 is flip-chip mounted on the mounting area 2a of the portion of the mother wiring board 2A which is to be the wiring board 2.

In the present invention, since the opening 17 which escapes the protruding portion 4a of the first encapsulant 4 sticking out from the surroundings of the chip stack body 3 is provided in the insulating film 11 covering one surface of the mother wiring board 2A, while avoiding interference of the protruding portion 4a with the mother wiring board 2A, between the other surface of the IF chip 12e and the one surface of the mother wiring board 2A (the mounting area 2a of the portion which is to be the wiring board 2), it is possible to appropriately bond the second bump electrode 13b and the pad electrode 7 therebetween via the wire bump 15.

Since the wire bump 15 is formed on the pad electrode 7 in a convex shape, it is possible to reduce diameters of the second bump electrode 13b of the IF chip 12e connected to the wire bump 15 and a through electrode 14 connected to the second bump electrode 13b.

Further, it is possible to suppress occurrence of chip cracks with the through electrode 14 as a starting point due to a reduction in the diameter of the through electrode 14.

Further, the adhesive member 16 is hardened in the state where the adhesive member 16 sticks out from between the one surface of the mother wiring board 2A and the other surface of the IF chip 12e. Therefore, the chip stack body 3 encapsulated by the first encapsulant 4 is adhered and fixed to the mounting area 2a of the portion of the mother wiring board 2A which is to be the wiring board 2 via the adhesive member 16.

Further, the first encapsulant 4 sticking out from the surroundings of the chip stack body 3 has a reverse tapered shape which gradually widens from a lower layer side toward an upper layer side in a width direction with the chip stack body 3 mounted in the portion which is to be the wiring board 2. In the present invention, since the first encapsulant 4 having the reverse tapered shape suppresses elevation of the adhesive member 16 sticking out from between the one surface of the mother wiring board 2A and the other surface of the IF chip 12e, it is possible to reduce occurrence of breakage or bonding failure of the chip stack body 3 due to sticking of the adhesive member 16 to the bonding tool 600.

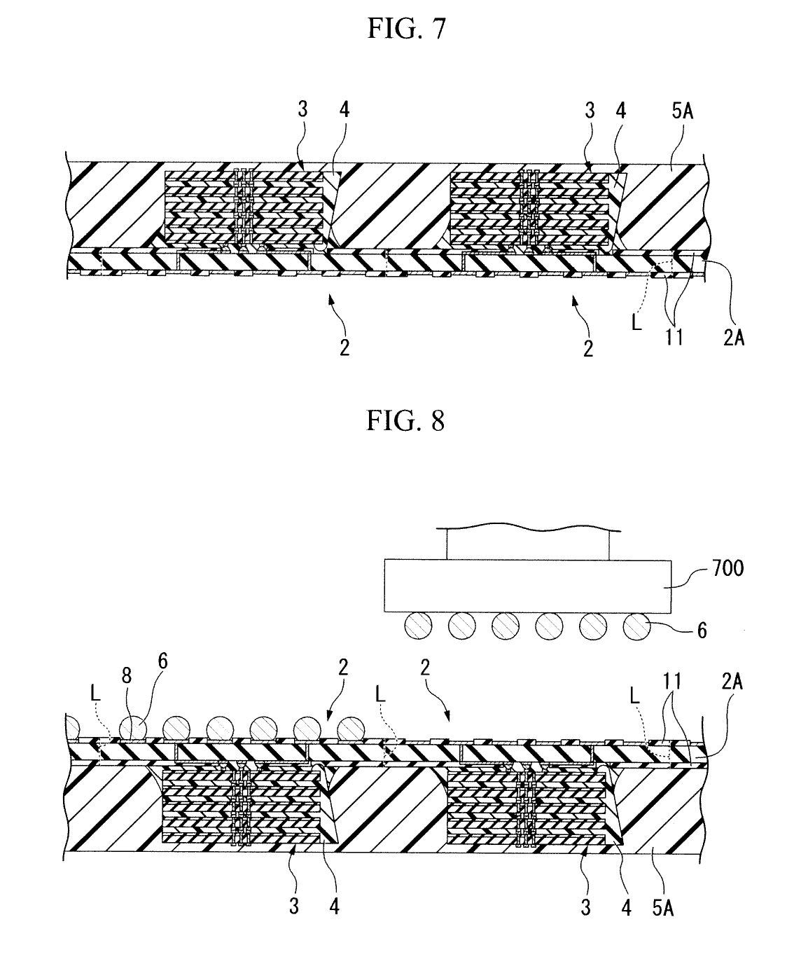

Next, as shown in FIG. 7, a mold resin 5A which is to be the second encapsulant 5 encapsulates one surface side of the mother wiring board 2A to cover the chip stack body 3 encapsulated by the first encapsulant 4. Specifically, a transfer molding apparatus (not shown) is used. The transfer molding apparatus includes a pair of mold dies constituted of a lower mold (fixed type) holding the other surface of the mother wiring board 2A and an upper mold (movable type) configured to form a cavity space in which the molding resin 5A is filled and which faces the one surface of the mother wiring board 2A and simultaneously detachably move with respect to the lower mold.

After the mother wiring board 2A on which the chip stack body 3 encapsulated by the first encapsulant 4 is mounted is set to the mold dies of the transfer molding apparatus, the heated and melted mold resin 5A is injected into the cavity space inside the mold dies. As the mold resin 5A, for example, a thermosetting resin such an epoxy resin is used.

In this state, the mold resin 5A is heated (cured) to a predetermined temperature (for example, about 180° C.) so that the mold resin 5A is hardened. Further, the mold resin 5A is baked at a predetermined temperature and completely hardened. Thereby, the one surface of the mother wiring substrate 2A is completely encapsulated by the mold resin 5A which is to be the second encapsulant 5.

In the present invention, as described above, after the chip stack body 3 encapsulated by the first encapsulant 4 is mounted on the mother wiring board 2A, the mother wiring board 2A is bulkily encapsulated by the mold resin 5A which is to be the second encapsulant 5 so that occurrence of voids (bubbles) can be reduced.

Next, as shown in FIG. 8, the above-described solder ball 6 is disposed on the connection land 8 provided in the portion of the mother wiring board 2A which is to be each wiring board 2. Specifically, using a mounting tool 700 of a ball mounter in which a plurality of suction holes (not shown) are formed, while a plurality of solder balls 6 are suctioned and held by the mounting tool 700, after flux is transferred and formed in the plurality of solder balls, the solder balls 6 are placed on the connection lands 8 in each portion of the mother wiring board 2A which is to be each wiring board 2. After the solder balls 6 are placed in all portions of the mother wiring board 2A which are to be the wiring boards 2, the mother wiring board 2A is reflowed. Thereby, the solder balls 6 are placed on the connection lands 8 of the portion of the mother wiring board 2A which is to be each wiring board 2.

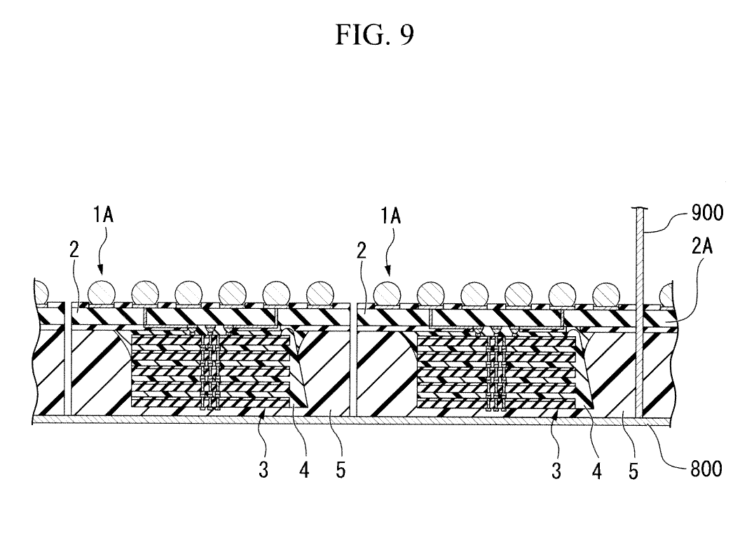

As shown in FIG. 9, the mother wiring board 2A is divided into individual semiconductor packages by cutting each portion thereof which is to be the wiring board 2. Specifically, after a dicing tape 800 is attached to the side of the second encapsulant 5 of the mother wiring board 2A, the mother wiring board 2A is cut from a side opposite the dicing tape 800 along a dicing line L using a dicing blade 900. Thereby, each semiconductor package 1A is divided. Further, the semiconductor package 1A is peeled off from the dicing tape 800 so that the semiconductor package 1A shown in FIG. 1A can be obtained.

As described above, in the present invention, since the opening 17 which escapes the protruding portion 4a of the first encapsulant 4 sticking out from the surroundings of the chip stack body 3 is provided in the insulating film 11 covering one surface of the mother wiring board 2A in each portion which is to be the wiring board 2, while avoiding interference of the protruding portion 4a with the mother wiring board 2A, between the other surface of the above-described IF chip 12e and the one surface (the mounting area 2a of the portion which is to be the wiring board 2) of the mother wiring board 2A, it is possible to appropriately bond the second bump electrode 13b and the pad electrode 7 therebetween via the wire bump 15. Therefore, according to the present invention, it is possible to fabricate the semiconductor package 1A having high connection reliability between the chip stack body 3 and the wiring board 2, while promoting the thinning of the chip stack body 3.

The present invention is not necessarily limited to the above embodiment and it is possible to add various modifications without departing from the scope and spirit of the present invention. In the following description, the same portions as in the semiconductor package 1A shown in FIG. 1 will be assigned the same reference numerals and not described.

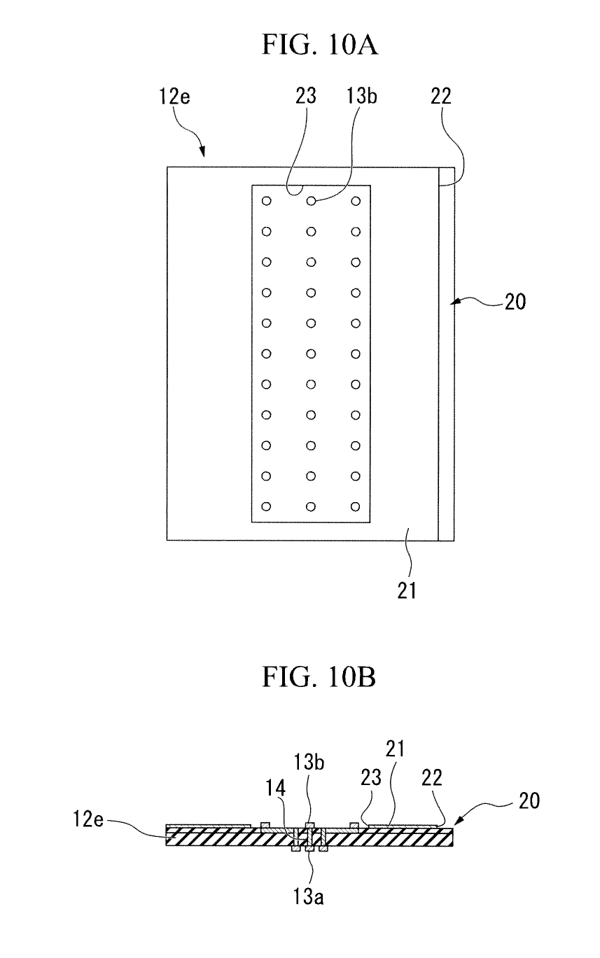

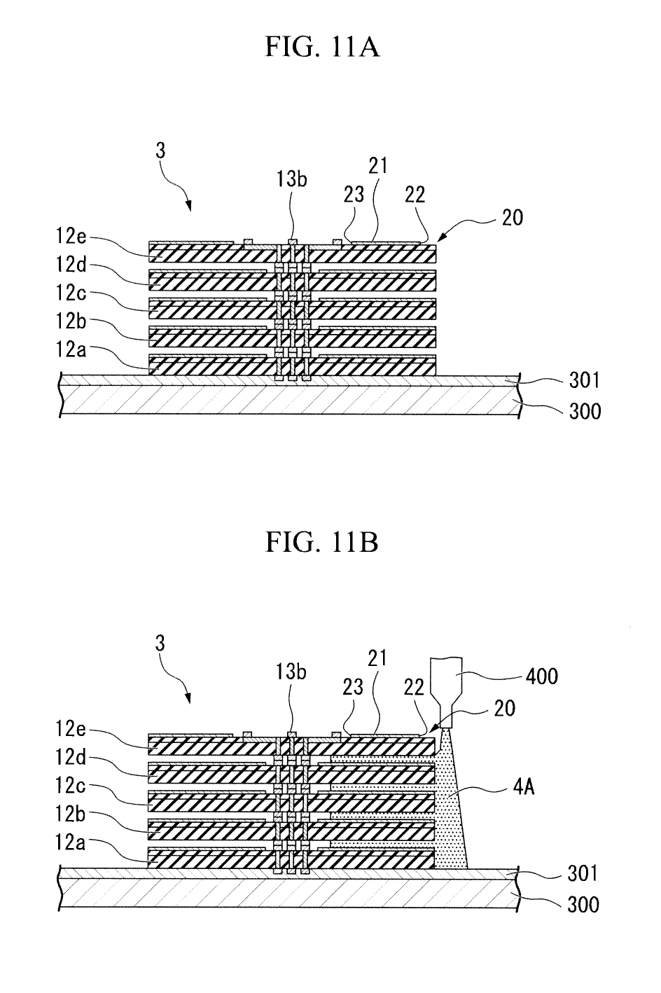

Specifically, as shown in FIGS. 10A and 10B, for example, in the present invention, the chip stack body 3 may be configured such that the IF chip 12e positioned in the uppermost layer thereof has a step unit 20 in a position corresponding to the protruding portion 4a of the first encapsulant 4.

The step unit 20 is formed by an opening 22 opened in an end edge portion of the IF chip 12e, among a protection film 21 formed of, for example, polyimide, or the like covering a surface of the IF chip 12. The opening 22 is provided along one side of the IF chip 12e in which the protruding portion 4a is to be formed. Further, an opening 23 exposing an area in which the above-described second bump electrode 13b is formed is formed in the protection film 21.

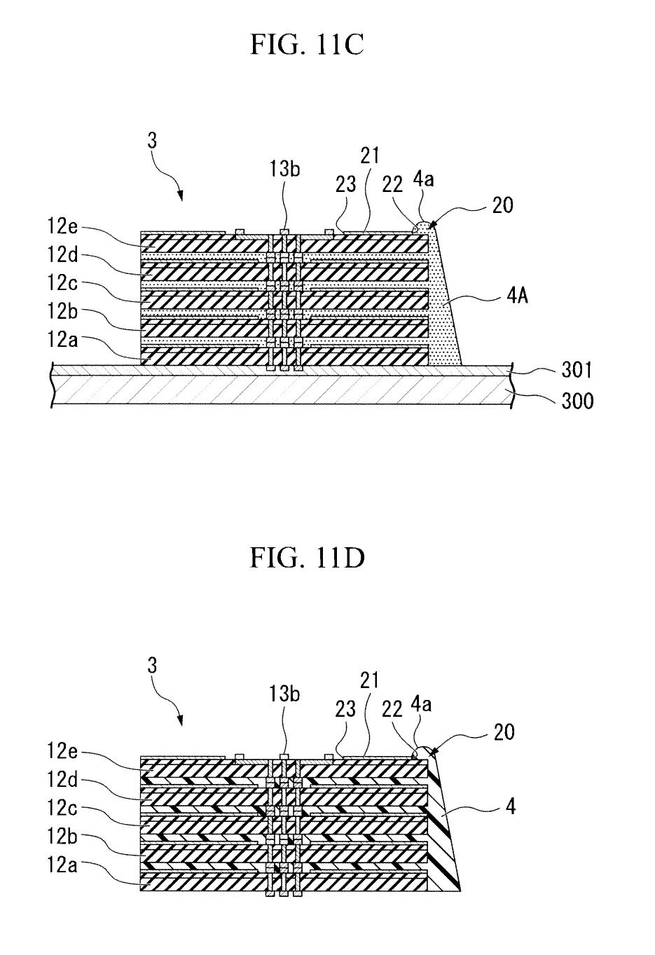

As shown in FIG. 11, when the chip stack body 3 is placed on the coating stage 300, as shown in FIG. 11B, using the dispenser 400 supplying the liquid underfill material 4A, the underfill material 4A is coated from the vicinity of an end portion of the position along one side of the chip stack body 3 toward each gap of the chip stack body 3 so that the underfill material 4A penetrates and is filled within each gap of the chip stack body 3 by a capillary action.

At this time, in the position along the one side of the chip stack body 3, as shown in FIG. 11C, the underfill material 4A sticking out from the surroundings of the chip stack body 3 from each gap of the chip stack body 3 protrudes to an upper surface of the IF chip 12e positioned in the uppermost layer so that the protruding portion 4a elevated upward more than the surface of the IF chip 12e is formed.

In the case of the configuration using the IF chip 12e shown in FIGS. 10A and 10B, since the underfill material 4A protruding to the upper surface of the IF chip 12e is dammed by the step unit 20 provided to the IF chip 20, the underfill material 4A is suppressed from spreading on the IF chip 12e. Further, the step unit 20 prevents the underfill material 4A from flowing to the side of the second bump electrode 13b.

From this state, the underfill material 4A is heated (cured), for example, at about 150° C. so that the underfill material 4A is hardened. Thereby, as shown in FIG. 11D, the chip stack body 3 encapsulated by the first encapsulant 4 stabilizes the shape of the protruding portion 4a of the first encapsulant 4. Moreover, it is possible to reduce the height of the protruding portion 4a by providing the step unit 20.

Therefore, in the case of this configuration, when the chip stack body 3 is mounted on the wiring board 2, since a distance (margin) to which the protruding portion 4a interferes with the wiring board 2 is ensured, it is possible to bond the second bump electrode 13b and the pad electrode 7 between the other surface of the IF chip 12e and the one surface of the wiring board 2 via the wire bump 15 in a more stable state.

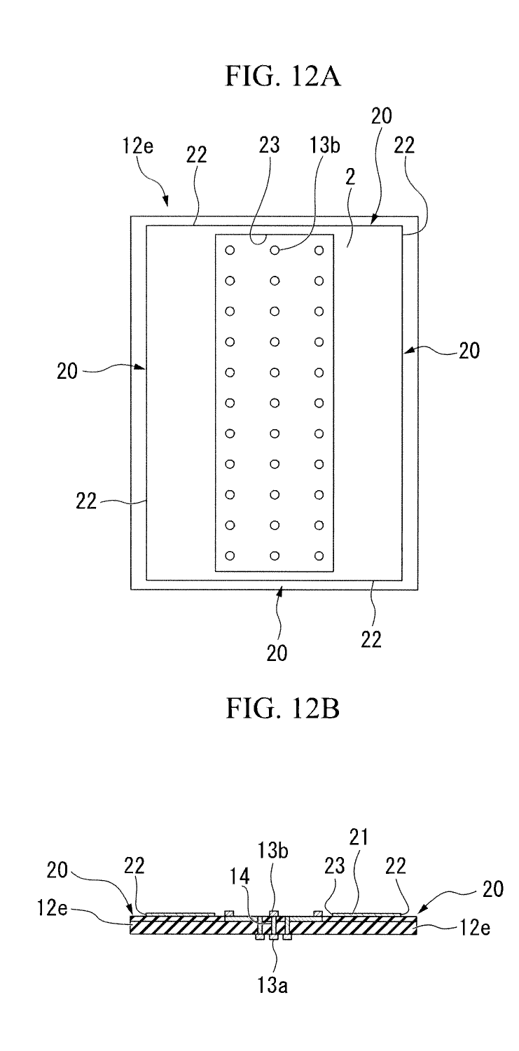

The IF chip 12e shown in FIGS. 10A and 10B is configured with the opening 22 forming the step unit 20 provided along one side of the IF chip 12e, but is not limited to this configuration. For example, as shown in FIGS. 12A and 12B, the IF chip 12e may be configured with the opening 22 forming the step unit 20 provided over all sides of the IF chip 12e.

In this configuration, the underfill material 4A protruding to the upper surface of the IF chip 12e surrounds the surroundings of the IF chip 12e along the step unit 20 to reduce the height of the protruding portion 4a. Therefore, in this configuration, when the chip stack body 3 is mounted on the wiring board 2, since a distance (margin) to which the protruding portion 4a interferes with the wiring board 2 is further ensured, it is possible to bond the second bump electrode 13b and the pad electrode 7 between the other surface of the IF chip 12e and the one surface of the wiring board 2 via the wire bump 15 in a more stable state.

The semiconductor package 1A shown in FIG. 1A is configured such that the opening 18 exposing the area in which the pad electrode 7 is formed is provided in the insulating film 11 covering one surface of the wiring board 2, and the opening 17 escaping the protruding 4a of the first encapsulant 4 is provided separately from the opening 18, but it is not limited to this configuration. For example, like a semiconductor package 1B shown in FIG. 1B, it may be configured such that an opening 19 in which the openings 17 and 18 are successively connected is formed.

However, in the configuration shown in FIG. 1B, since balance of the insulating film 11 formed in either side of the wiring board 2 becomes bad, warpage of the wiring board 2 is likely to occur and an exposed area of a conductor pattern such as the pad electrode 7 or the wiring pattern 10 becomes large. In this case, due to poor adhesion between the wiring pattern 10 formed of Au-plated Cu and the adhesion member 16 formed of an NCP, the adhesion of the adhesion member 16 to the wiring board 2 is degraded and the above-described surface is likely to be peeled off.

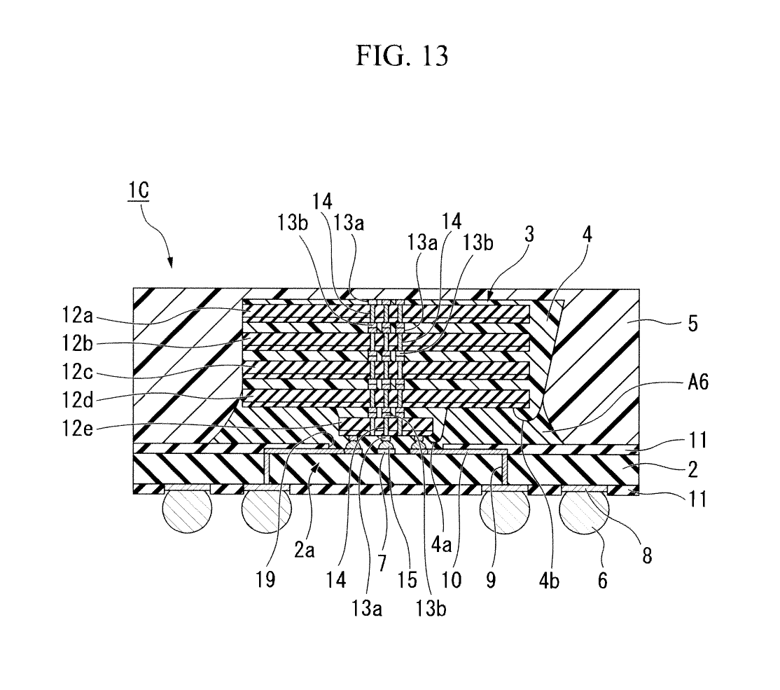

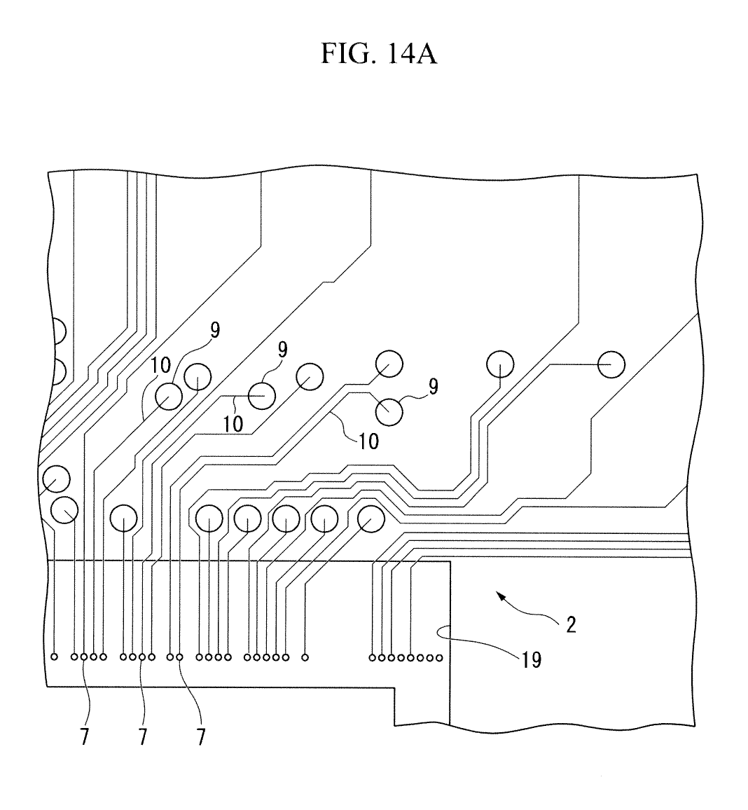

In the present invention, for example, like a semiconductor package 1C shown in FIG. 13, the IF chip 12e positioned in the uppermost layer of the chip stack body 3 has a smaller size then the memory chips 12a to 12d.

In this case, the opening 19 escaping the protruding portion 4a of the first encapsulant 4 is opened larger than the IF chip 12e to prevent the protruding portion 4a from interfering with the wiring board 2. But, like the semiconductor package 1B shown in FIG. 1B, since the size of the opening 19 can be reduced compared to the IF chip 12e having the same size as the memory chips 12a to 12d, it is possible to improve adhesion of the adhesion member 16 to the wiring board 2.

When the IF chip 12e is smaller than the memory chips 12a to 12d, the underfill material sticking out from the surroundings of the chip stack body 3 protrudes to the upper surface of the memory chip 12d positioned directly below the IF chip 12e and thus a protruding portion 4b elevated upward from the upper surface of the memory chip 12d is formed. However, since the protruding portion 4b is positioned sufficiently lower than the IF chip 12e, it is possible to avoid interference with the wiring board 2.

In the present invention, a via 9 penetrating the wiring board 2 is preferably disposed in an area covered by the insulating film 11 further out than the opening 19. In this case, exposure of the wiring pattern 10 having poor adhesion with the adhesion member 16 from the opening 19 can be reduced. On the other hand, since a surface of an insulating base material having good adhesion with the adhesion member 16 is largely exposed from the opening 19, it is possible to further improve the adhesion of the adhesion member 16 to the wiring substrate 2.

In this case, in the area penetrating the opening 19 of the wiring board 2 in a thickness direction thereof, only the pad electrode 7 and the wiring pattern 10 connected thereto are positioned in one surface (upper surface) side. In the other surface (lower surface) of the wiring board 2, the connection land 8, the via 9, and a wiring pattern (not shown) drawn therebetween are disposed in the area that is further out than the opening 19 so that it is possible to promote a reduction of a wiring capacitance in the wiring board 2.

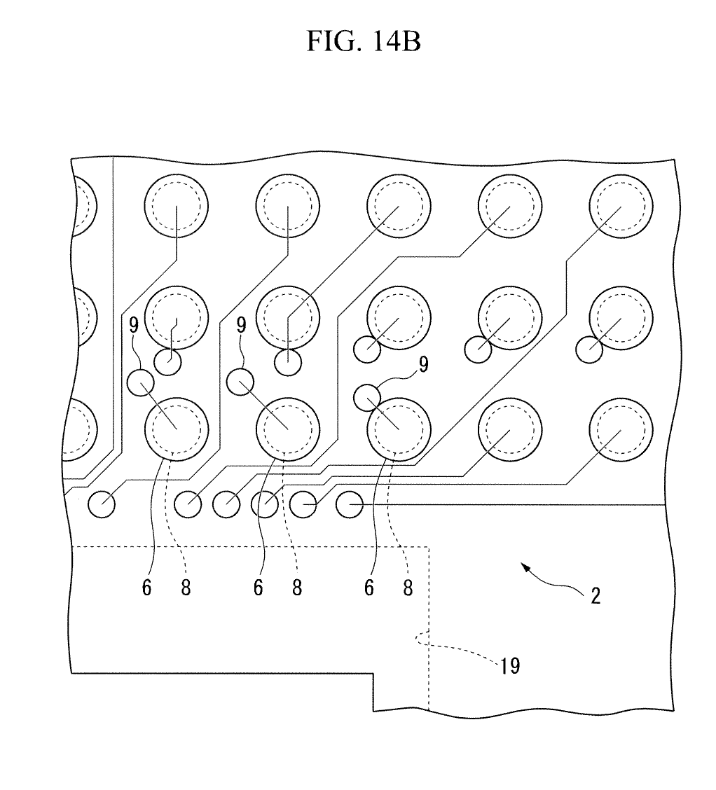

In the present invention, as shown in FIGS. 14A and 14B, the via 9 is preferably disposed in the vicinity of the solder ball 6 (the connection land 8) positioned closest to the pad electrode 7. In this case, it is possible to suppress imbalance of capacitance in the wiring pattern 10 withdrawn between the connection land 8 in which a corresponding solder ball is disposed and the via 9 disposed in the vicinity thereof.

Next, a method of fabricating the semiconductor package 1C will be described.

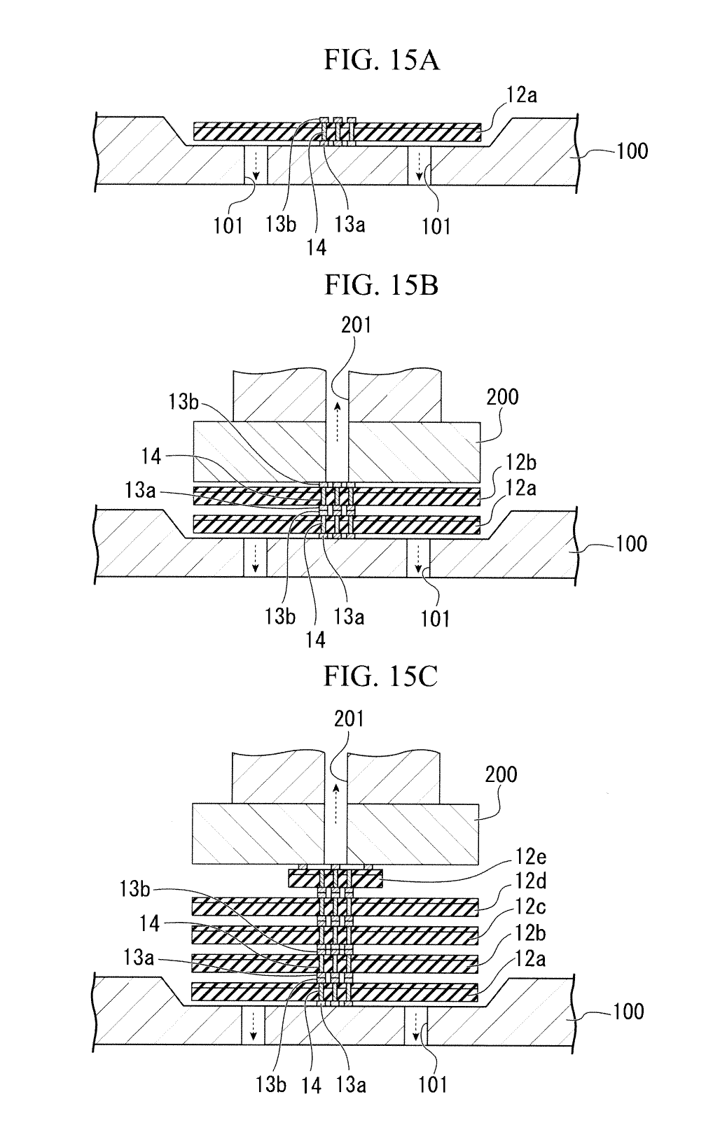

When the semiconductor package 1C shown in FIG. 13 is fabricated, first, as shown in FIGS. 15A to 15C, the plurality of semiconductor chips 12a to 12e are stacked by bonding the first bump electrode 13a and the second bump electrode 13b between each one surface and each other surface of the semiconductor chips 12a to 12e, while facing the one surface and the other surface.

Specifically, as shown in FIG. 15A, the memory chip 12a of a first layer is placed on the suction stage 100 such that one surface thereof in which the plurality of first bump electrodes 13a are formed faces downward. Further, the memory chip 12a is held on the suction stage 100 by suctioning the memory chip 12a by the plurality of suction holes 101 provided in the suction stage 100.

From this state, as shown in FIG. 15B, using the bonding tool 200, the memory chip 12b of a second layer is stacked and mounted (flip-chip mounted) on the memory chip 12a of the first layer. In flip-chip mounting, while the memory chip 12b of the second layer is suctioned and held by the suction hole 201 provided in the bonding tool 200, the memory chip 12b is held by the bonding tool 200 such that the surface (one surface) of the memory chip 12b in which the first bump electrode 13a is formed faces downward.

While the bonding tool 200 faces the one surface of the memory chip 12b of the second layer to the other surface of the memory chip 12a of the first layer, the bonding tool 200 places the memory chip 12b of the second layer on the memory chip 12a of the first layer such that the first bump electrode 13a and the second bump electrode 13b \ between the one surface of the memory chip 12b and the other surface of the first memory 12a are aligned with each other. Further, in this state, the first bump electrode 13a and the second bump electrode 13b are bonded (flip-chip bonded) by thermo-compression by heating at a high temperature (for example, 300° C.) and applying weight by the bonding tool 200. In bonding, ultrasonic waves as well as weight may be applied.

Therefore, the first bump electrode 13a and the second bump electrode 13b are electrically connected (flip-chip connected) and thus the memory chip 12b of the second layer is flip-chip mounted on the memory 12a of the first layer.

Using the same method as when the memory chip 12b of the second layer is flip-chip mounted on the memory chip 12a of the first layer, the memory chip 12c of a third layer on the memory chip 12b of the second layer, and the memory chip 12d of a fourth layer on the memory chip 12c of the third layer are flip-chip mounted in order.

Furthermore, from this state, as shown in FIG. 15C, the IF chip 12e of a fifth layer is flip-chip mounted on the memory chip 12d of the fourth layer. Thereby, the chip stack body 3 in which the plurality of semiconductor chips 12a to 12e are stacked can be obtained.

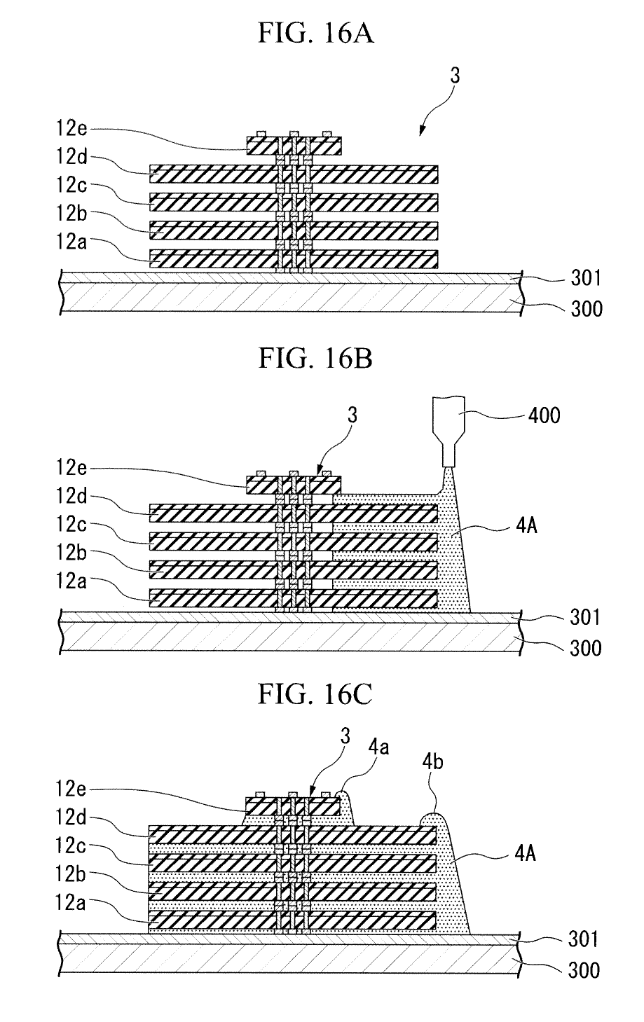

Next, as shown in FIGS. 16A to 16C, the underfill material 4A which is to be the first encapsulant 4 is filled between each gap of the chip stack body 3 in which the plurality of semiconductor chips 12a to 12e are stacked to encapsulate the chip stack body 3.

Specifically, as shown in FIG. 16A, the chip stack body 3 is placed on the coating stage 300. For example, a coating sheet 301 formed of a material having a poor wettability with the first underfill material 4A such as a fluorine-based sheet or a sheet to which a silicon-based adhesion material is attached is stuck on the surface of the coating stage 300.

From this state, as shown in FIG. 16B, using the dispenser 400 supplying the liquid underfill material 4A, the underfill material 4A is coated from the vicinity of an end portion of a position along one side of the chip stack body 3 toward each gap of the chip stack body 3. At this time, the underfill material 4A penetrates and is filled within each gap of the chip stack body 3 by a capillary action.

Here, in the position along one side of the chip stack body 3, as shown in FIG. 16C, among the gaps of the chip stack body 3, the underfill material 4A sticking out from the surroundings between the IF chip 12e positioned in the uppermost layer and the memory chip 12d of the fourth layer positioned directly below the IF chip 12e protrudes to the upper surface of the IF chip 12e so that the protruding portion 4a elevated upward from the upper surface of the IF chip 12e is formed. Further, the underfill material 4A sticking out from the surroundings between the memory chip 12d of the fourth layer and the memory chip 12c of the third layer positioned directly below the memory chip 12d protrudes to the upper surface of the memory chip 12d of the fourth layer and thus the protruding portion 4b elevated upward from the upper surface of the memory chip 12d is formed.

Since the underfill material 4A sticking out from the surroundings from each gap of the plurality of memory chips 12a to 12d is suppressed from spreading within the surface by the coating sheet 301 having a poor wettability with the above-described underfill material 4A, even when the underfill material 4A gradually spreads to a width direction from an upper layer side to a lower layer side, it is possible to reduce the width of the underfill material 4A.

From the state, the underfill material 4A is hardened by heating (curing), for example, at about 150° C. Thereby, the chip stack body 3 encapsulated by the first encapsulant 4 is formed.

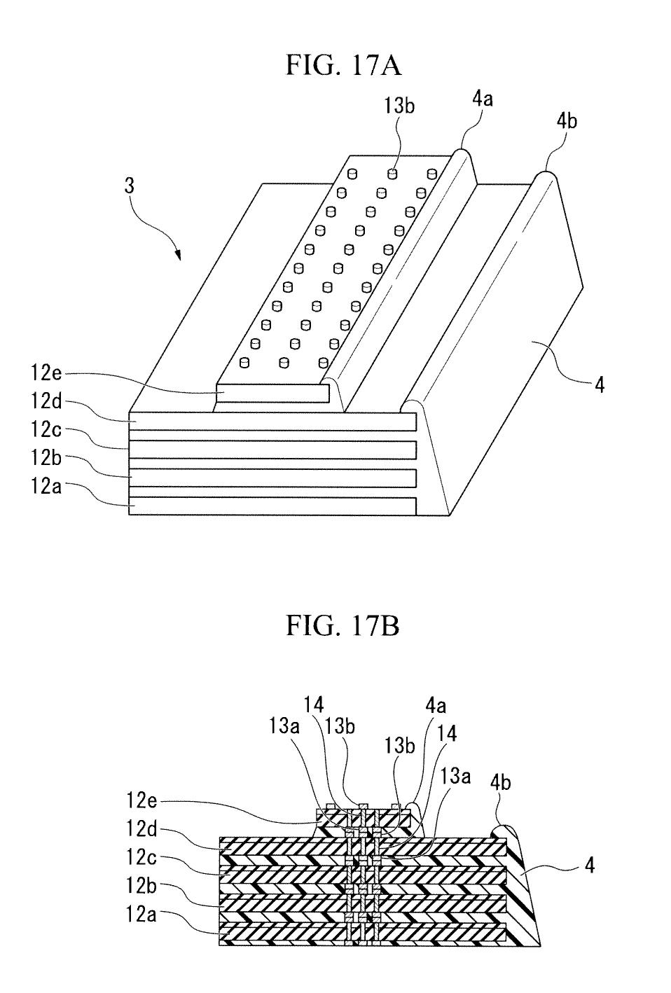

As shown in FIGS. 17A and 17B, the chip stack body 3 encapsulated by the first encapsulant 4 is peeled off from the coating sheet 300. At this time, it is possible to easily peel off the chip stack body 3 encapsulated by the first encapsulant 4 from the coating sheet 301 having a poor wettability with the above-described underfill material 4A. The chip stack body 3 encapsulated by the first encapsulant 4 is contained in a tray for storage (not shown) and transferred to a subsequent process.

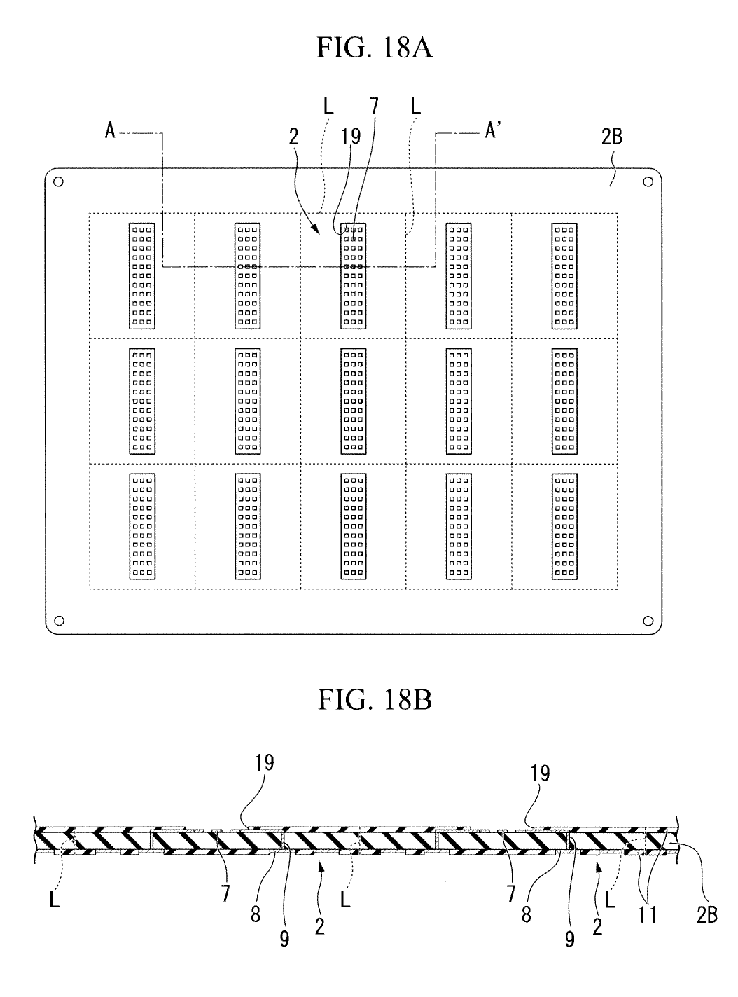

As shown in FIGS. 18A and 18B, a mother wiring board 2B, in which a plurality of portions which are to be the wiring boards 2 are formed in parallel, is prepared. For example, the plurality of portions of the mother wiring board 2B which are to be the wiring boards 2 formed of a glass epoxy board are formed in parallel in a matrix form and finally cut along the dicing line L so that it is possible to cut the portions of the mother wiring board 2B which are to be the wiring boards 2 as individual wiring boards 2. Further, in the insulating film covering one surface of the mother wiring board 2B, an opening 19 escaping the protruding portion 4a of the first encapsulant 4 sticking out from the surroundings of the chip stack body 3 is continuously formed to an opening exposing an area in which the pad electrode 7 is formed

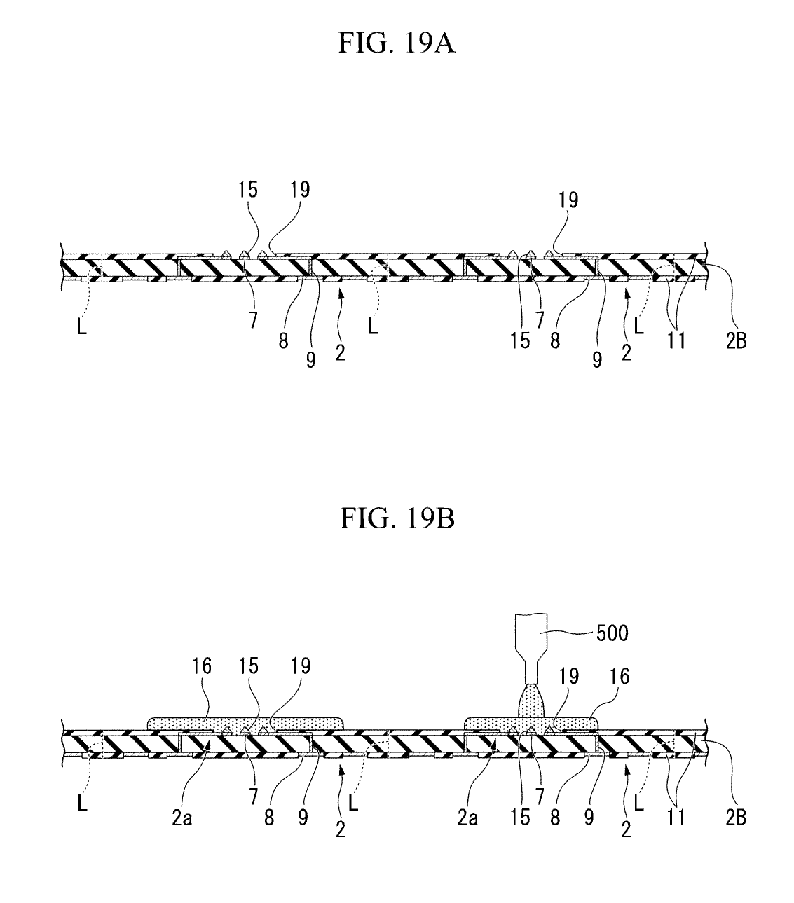

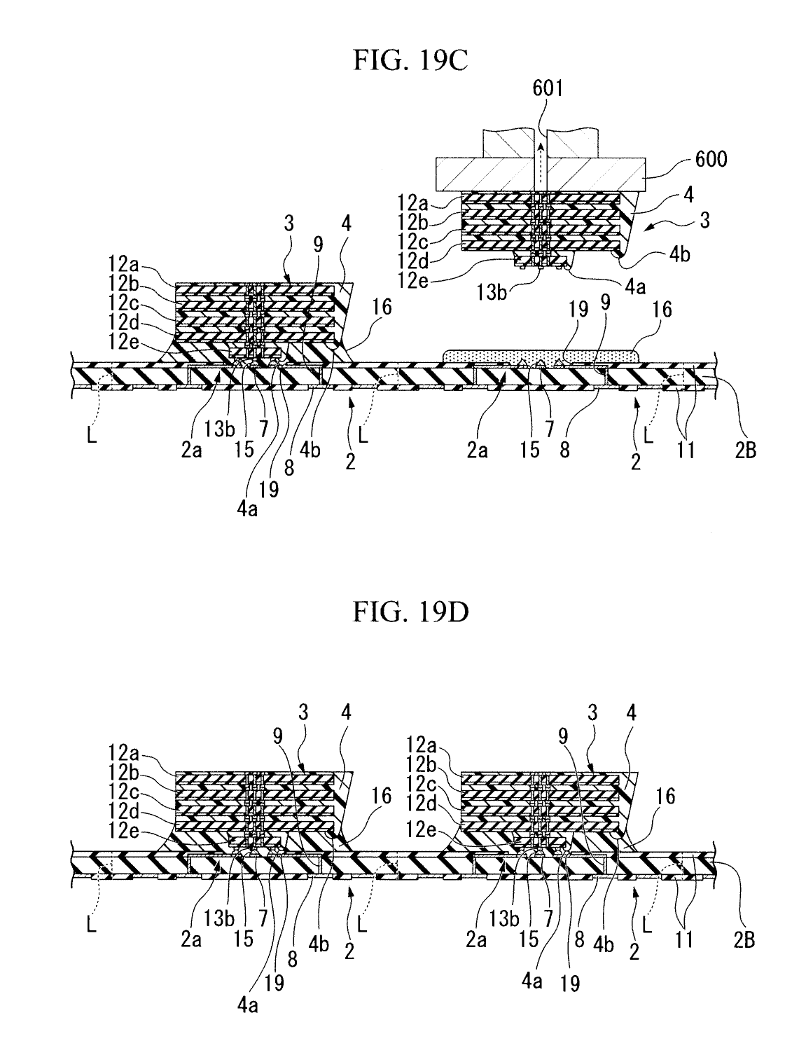

As shown in FIGS. 19A to 19D, in one surface of the mother wiring board 2B, the chip stack body 3 encapsulated by the first encapsulant 4 is mounted on each portion which is to be the wiring board 2.

Specifically, as shown in FIG. 19A, a wire bump 15 is disposed on each pad electrode 7 of each of the portions which are to be the wiring board 2. The wire bump 15 is formed by forming a melted ball in a front end of a wire formed of, for example, Au, Cu, or the like, bonding the ball on the pad electrode 7 using a wire bonding apparatus (not shown) by ultrasonic thermocompression and then pulling and cutting a rear end of the wire.

From this state, as shown in FIG. 19B, using the dispenser 500 supplying a liquid adhesion member 16 referred to as an NCP, the adhesion member 16 is coated in each mounting area 2a of the portion which is to be the wiring board 2 on the mother wiring board 2B.

From this state, as shown in FIG. 19, using the bonding tool 600, the chip stack body 3 is flip-chip mounted in the mounting area 2a of the portion of the mother wiring board 2B which is to be the wiring board 2. In flip-chip mounting, while the chip stack body 3 is suctioned and held by the suction hole 601 of the bonding tool 600, the bonding tool 600 holds the chip stack body 3 such that the IF chip 12e faces downward.

While the IF chip 12e and the mounting area 2a of the portion which is to be the wiring board 2 face each other, the bonding tool 600 places the chip stack body 3 encapsulated by the first encapsulant 4 on the mounting area 2a of the portion which is to be the wiring board 2 such that positions of the second bump electrode 13b and the pad electrode 7 between the IF chip 12e and the mounting area 2a are aligned with each other. In this state, while the bonding tool 600 heats at a high temperature (for example, about 300° C.) and applies weight, the second bump electrodes 13b and the pad electrodes 7 are bonded (flip-chip bonded) by thermocompression. In bonding, ultrasonic waves as well as weight may be applied.

Thereby, as shown in FIG. 19D, the second bump electrode 13b and the pad electrode 7 are electrically connected via the wire bump 15 and the chip stack body 3 encapsulated by the first encapsulant 4 is flip-chip mounted in the mounting area 2a of each portion of the mother wiring board 2B which is to be the wiring board 2.

In the present invention, since the opening 19 which escapes the protruding portion 4a of the first encapsulant 4 sticking out from the surroundings of the chip stack body 3 is provided in the insulating film 11 covering one surface of the mother wiring board 2B, while avoiding interference of the protruding portion 4a with the mother wiring board 2B, between the other surface of the IF chip 12e and the one surface (the mounting area 2a of the portion which is to be the wiring board 2) of the mother wiring board 2B, it is possible to appropriately bond the second bump electrode 13b and the pad electrode 7 therebetween via the wire bump 15.

Since the wire bump 15 is formed on the pad electrode 7 in a convex shape, it is possible to reduce diameters of the second bump electrode 13b of the IF chip 12e connected to the wire bump 15 and the through electrode 14 connected to the second bump electrode 13b.

Further, by reduction of the diameter of the through electrode 14, it is possible to suppress occurrence of chip cracks with the through electrode 14 as a starting point.

The adhesion member 16 is hardened in the state where the adhesion member 16 protrudes from between the one surface of the mother wiring board 2B and the other surface of the IF chip 12e. Thereby, the chip stack body 3 encapsulated by the first encapsulant 4 is adhered and fixed to the mounting area 2a of each portion of the mother wiring board 2B which is to be the wiring substrate 2 via the adhesion member 16.

The first encapsulant 4 sticking out from the surroundings of the chip stack body 3 has a reverse tapered shape in which the first encapsulant 4 gradually widens from a lower layer side to an upper layer side in the width direction when the chip stack body 3 is mounted in the portion which is to be the wiring board 2. In the present invention, since the elevation of the adhesion member 16 sticking out between the one surface of the mother wiring board 2B and the other surface of the IF chip 12e may be suppressed by the first encapsulant 4 having the reverse tapered shape, it is possible to reduce occurrence of breakage or bonding failure of the chip stack body 3 due to sticking of the adhesive member 16 to the bonding tool 600.

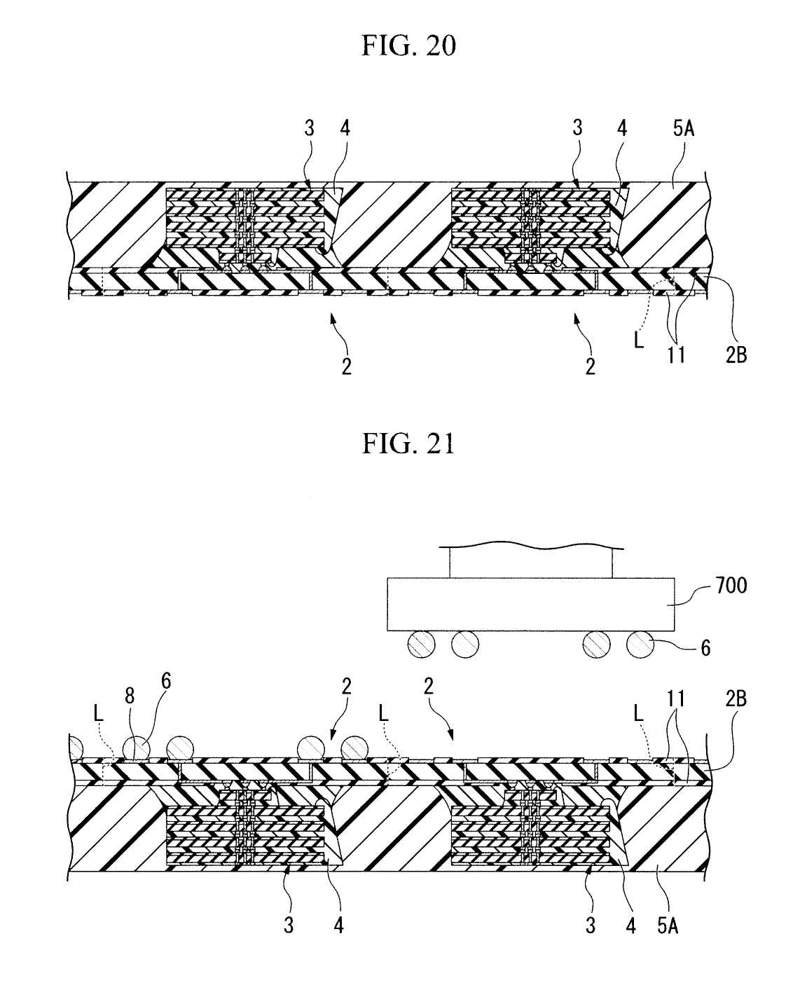

As shown in FIG. 20, one surface side of the mother wiring board 2B is encapsulated by a mold resin 5A which is to be the second encapsulant 5 to cover the chip stack body 3 encapsulated by the first encapsulant 4. Specifically, a transfer molding apparatus (not shown) is used. The transfer molding apparatus includes a pairs of mold dies constituted of a lower mold (fixed type) holding the other surface side of the mother wiring board 2B and an upper mold (movable type) which form a cavity space filled with the mold resin 5A by facing one surface side of the mother wiring board 2B and is detachably moved relatively with respect to the lower mold.

After the mother wiring board 2B in which the chip stack body 3 encapsulated by the first encapsulant 4 is mounted is set to the mold dies of the transfer molding apparatus, the heated and melted mold resin 5A is injected into the cavity space within the mold dies. For example, as the mold resin 5A, a thermosetting resin such as an epoxy resin is used.

From the state, the mold resin 5A is hardened by heating (curing) the mold resin 5A to a predetermined temperature (for example, about 180° C.). The mold resin 5A is baked at a predetermined temperature and thus the mold resin 5A is completely hardened. Thereby, the one surface side of the mother wiring board 2B is completely encapsulated by the mold resin 5A which is to be the second encapsulant 5.

In the present invention, as described above, since the mold resin 5A which is to be the second encapsulant 5 is bulkily encapsulated on the mother wiring board 2B after the chip stack body 3 encapsulated by the first encapsulant 4 is mounted on the mother wiring board 2B, occurrence of voids (bubbles) can be reduced.

Next, as shown in FIG. 21, the solder ball 6 is disposed on the connection land 8 provided in the portion of the mother wiring board 2B which is to be each wiring board 2. Specifically, while the plurality of solder balls 6 are suctioned and held by the mounting tool 700 using the mounting tool 700 of a ball mounter in which a plurality of suction holes (not shown) are formed, the solder ball 6 is placed on the connection land 8 in each portion of the mother wiring board 2B which is to be each wiring board 2. After the solder balls 6 are placed in all the portions of the mother wiring board 2B which are to be the wiring boards 2, the mother wiring board 2B is reflowed. Thereby, the solder ball 6 is disposed on the connection land 8 of the portion of the mother wiring board 2B which is to be each wiring board 2.

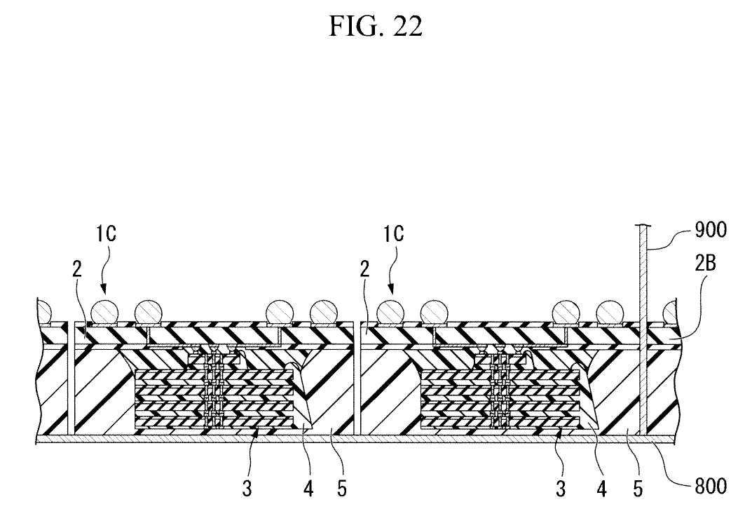

Next, as shown in FIG. 22, each portion of the mother wiring board 2B which is to be the wiring board 2 is cut so that the mother wiring board 2B is divided into individual semiconductor packages 1C. Specifically, after a dicing tape 800 is stuck to the second encapsulant 5 of the wiring mother board 2B, the mother wiring board 2B is cut along the dicing line L from a side opposite the dicing tape 800 using a dicing blade 900. Thereby, each semiconductor package 1C is divided. Further, the semiconductor package 1C is peeled off from the dicing tape 800, thereby obtaining the semiconductor package 1C shown in FIG. 13.

As described above, in the present invention, since the opening 19 which escapes the protrusion portion 4a of the first encapsulant 4 sticking out from the surroundings of the chip stack body 3 is provided in the insulating film 11 covering one surface of the mother wiring board 2B in each portion which is to be the wiring board 2, the interference of the protrusion portion 4a with the mother wiring board 2B is avoided and, between the other surface of the above-described IF chip 12e and the one surface (the mounting area 2a of the portion which is to be the wiring board 2) of the mother wiring board 2B, it is possible to appropriately bond the second bump electrode 13b and the pad electrode 7 therebetween via the wire bump 15. Therefore, according to the present invention, it is possible to promote the thinning of the chip stack body 3 and fabricate the semiconductor package 1C having high connection reliability between the chip stack body 3 and the wiring board 2.

The chip stack body 3 is configured with four memory chips 12a to 12d and one IF chip 12e stacked, but the number of the stacked memory chips can also be two or more. The present invention is not limited to the five-stage configuration and can also be configured of four stages or fewer or six stages or more. Further, in the chip stack body 3, it is possible to appropriately modify the arrangement of the first bump electrode 13a, the through electrode 14, and the second bump electrode 13b or the number thereof.

The chip stack body 3 is configured to be mounted on the wiring board 2 in the state where the IF chip 12e positioned in the uppermost layer faces downward, but it is possible to mount the chip stack body 3 on the wiring board 2 in the state where the memory chip 12a positioned in the lowermost layer faces downward.

The chip stack body 3 is configured to combine the memory chips 12a to 12d and the IF chip 12e, but it is possible to arbitrarily modify the type or size of the chip, or the like.

Further, the present invention is not limited to the BGA type semiconductor packages 1A and 1B. For example, the present invention can be applied to other semiconductor packages such as a land grid array (LGA) type, chip scale package (CSP) type, or the like.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a wiring board having a first surface, the wiring board including a first insulating layer formed over the first surface, and the first insulating layer having a first opening;
a stack of semiconductor chips mounted over the first surface of the wiring board, the stack of semiconductor chips including a first semiconductor chip, the first semiconductor chip being closer to the wiring board than the other semiconductor chips; and
a first sealing member that seals at least the first semiconductor chip, the first sealing member including a protruding portion,
wherein the first opening of the insulating layer faces toward the protruding portion of the first sealing member.

2. The semiconductor device according to claim 1, wherein the protruding portion is disposed in the first opening of the insulating layer.

3. The semiconductor device according to claim 1, wherein the protruding portion covers a first side of the first semiconductor chip.

4. The semiconductor device according to claim 3, further comprising:
a protecting film which covers a first surface of the first semiconductor chip, the first surface of the first semiconductor chip facing toward the first surface of the wiring board, the protecting film having a second opening, the second opening extending along the first side of the first semiconductor chip, and the second opening receiving the protruding portion.

5. The semiconductor device according to claim 1, further comprising:
a second sealing member formed over the first surface of the wiring board to cover the stack of semiconductor chips and the first sealing material.

6. The semiconductor device according to claim 1, wherein each of the semiconductor chips includes a via electrode, the semiconductor chips being electrically coupled with each other through the via electrode.

7. The semiconductor device according to claim 1, wherein the first semiconductor chip is smaller in size than the other semiconductor chips, the protruding portion of the first sealing member is positioned inside the other semiconductor chips in plan view.

8. The semiconductor device according to claim 7, further comprising:
a third sealing member that seals the other semiconductor chips except for the first semiconductor chip,
wherein the first sealing member seals the first semiconductor chip.

9. The semiconductor device according to claim 6, wherein the wiring board includes a connection pad formed on the first surface thereof, the connection pad is positioned in the first opening of the first insulating layer, the connection pad is electrically coupled to the via electrode of the semiconductor chips.

10. The semiconductor device according to claim 1, wherein the wiring board includes a via electrode which penetrates the wiring board, and the via electrode is positioned outside the first opening of the first insulating layer.

11. The semiconductor device according to claim 10, further comprising:
an external terminal formed over a second surface that is opposed to the first surface of the wiring board, the external terminal is positioned outside the first opening of the first insulating layer in plan view, the external terminal being electrically coupled to the connection pad through the via electrode.

12. A semiconductor device comprising:
a first semiconductor chip having a first surface, the first semiconductor chip including a first electrode formed on the first surface thereof;
a second semiconductor chip stacked over the first surface of the first semiconductor chip, the second semiconductor chip including a second electrode formed on a second surface thereof and a third electrode formed on a third surface thereof, the second surface facing the first surface of the first semiconductor chip so as to electrically couple the first electrode to the second electrode;
a first sealing member that seals at least the second semiconductor chip without covering the third electrode, and the first sealing member including a protruding portion that protrudes from the third surface of the second semiconductor chip; and
a wiring board stacked over the third surface of the second semiconductor chip and including an insulating layer formed on a fourth surface thereof, the insulating layer including an opening, the fourth surface facing the third surface of the second semiconductor chip so that the protruding portion of the first sealing member arranges in the opening of the insulating layer.

13. The semiconductor device according to claim 12, wherein the second semiconductor chip is smaller in size than the first semiconductor chip.

14. The semiconductor device according to claim 12, further comprising:
a third semiconductor chip provided between the first and second semiconductor chips and the third semiconductor chip including a fourth electrode formed on a fifth surface thereof and a fifth electrode formed on a sixth surface thereof, the fourth surface facing the first surface of the first semiconductor chip so as to electrically couple the first electrode to the fourth electrode, and the fifth surface facing the second surface of the second semiconductor chip so as to electrically couple the second electrode to the fifth electrode.

15. The semiconductor device according to claim 12, wherein the wiring board includes a connection pad formed on the fourth surface thereof, the connection pad is positioned in the opening of the insulating layer, and the connection pad is electrically coupled to the third electrode of the second semiconductor chip.

16. The semiconductor device according to claim 12, further comprising:
an external terminal provided over the seventh surface that is opposed to the fourth surface of the wiring board, the external terminal being electrically coupled to the connection pad through a via electrode;

17. The semiconductor device according to claim 16, wherein the external terminal and the via electrode are positioned outside the opening in plan view.

18. The semiconductor device according to claim 12, wherein the third surface of the second semiconductor chip includes an uneven portion adjacent to a first side thereof, the protruding portion of the first sealing member being disposed over the first side of the second semiconductor chip.

19. A semiconductor device comprising:
a first semiconductor chip including a first electrode formed on a first surface thereof;
a second semiconductor chip smaller than the first semiconductor chip staked over the first surface of the first semiconductor chip and the second semiconductor chip including a second electrode formed on a second surface thereof and a third electrode formed on a third surface thereof, the second surface facing toward the first surface of the first semiconductor chip so as to electrically couple the first electrode to the second electrode;
a first sealing member that seals at least the first semiconductor chip without covering the third electrode, and the first sealing member including a protruding portion that protrudes over the third surface of the second semiconductor chip; and
a wiring board stacked over the third surface of the second semiconductor chip and the wiring board including a connection pad formed on a fourth surface thereof and an insulating layer formed on the fourth surface, the insulating layer including an opening to expose the connection pad from the insulating layer, the fourth surface facing the third surface of the second semiconductor chip so as to electrically couple the third electrode to the connection pad,
wherein the opening of the insulating layer is larger in size than the second semiconductor chip, and is smaller in size than the first semiconductor chip, the second semiconductor chip is positioned in the opening in plan view, and the protruding portion of the first sealing member is disposed in the opening.

20. The semiconductor device according to claim 19, further comprising:
an external terminal provided over the fifth surface that is opposed to the fourth surface of the wiring board, the external terminal being electrically coupled to the connection pad through a via electrode,
wherein the external terminal and the via electrode are positioned outside the opening in plan view.
